(19) United States
(12) Patent Application Publication
(10) Pub. No.: US 2026/0181890 A1
(43) Pub. Date: Jun. 25, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventor: SEOKCHEON BAEK, Suwon-si (KR)

(21) Appl. No.: 19/248,566

(22) Filed: Jun. 25, 2025

(30) Foreign Application Priority Data
Dec. 19, 2024 (KR) 10-2024-0191831

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

A semiconductor device includes a cell array region, a connection region including first and second regions, a stacking structure including a gate stacking structure and an insulation stacking structure, a channel structure passing through the gate stacking structure, and gate contacts in the second region and electrically connected to at least a part of the gate electrodes in the first region. The gate stacking structure includes gate electrodes and interlayer insulation layers. The insulation stacking structure includes sacrificial insulation layers and the interlayer insulation layers. Each gate contacts includes a conductive portion and a side insulation layer. The conductive portion includes a penetration part and a connection part extending horizontally to have an area greater than an area of the penetration part. The penetration part of a first contact of the gate contacts includes first and second portions on respective first and second surfaces of the connection part.

### CROSS-REFERENCE TO RELATED APPLICATION

This application claims priority under 35 U.S.C. § 119 to and the benefit thereof Korean Patent Application No. 10-2024-0191831, filed on Dec. 19, 2024, with the Korean Intellectual Property Office, the entire contents of which are incorporated herein by reference.

### BACKGROUND

### (a) Field

The present disclosure relates to a semiconductor device and an electronic system including the same, and more particularly, to a semiconductor device having an improved structure and an electronic system including the same.

### (b) Description of the Related Art

In an electronic system implementing a data storage, a semiconductor device capable of storing high-capacity data is in demand. Accordingly, a method for increasing a data storage capacity of a semiconductor device is being researched. For example, as one method for increasing the data storage capacity of a semiconductor device, a semiconductor device including three-dimensionally arranged memory cells instead of two-dimensionally arranged memory cells has been proposed.

### SUMMARY

The present disclosure provides a semiconductor device capable of enhancing performance and reliability and an electronic system including the same.

A semiconductor device according to an embodiment includes a cell array region, and a connection region including a first region and a second region. The semiconductor device includes a stacking structure, a channel structure, and a plurality of gate contacts. The stacking structure includes a gate stacking structure and an insulation stacking structure. The gate stacking structure is in the cell array region and the first region, and includes a plurality of gate electrodes and a plurality of interlayer insulation layers. The insulation stacking structure is in the second region, and includes a plurality of sacrificial insulation layers and the plurality of interlayer insulation layers. The channel structure passes through the gate stacking structure in the cell array region. The plurality of gate contacts is in the second region and are electrically connected to at least a part of the plurality of gate electrodes in the first region, respectively. Each of the plurality of gate contacts includes a conductive portion and a side insulation layer. The conductive portion includes a penetration part passing through the insulation stacking structure and a connection part extending horizontally to have an area greater than an area of the penetration part. The side insulation layer is on at least a portion of a side surface of the conductive portion. The plurality of gate contacts includes a first contact. The connection part has a first surface and a second surface opposite to each other. The penetration part of the first contact includes a first portion on the first surface of the connection part and a second portion on the second surface of the connection part.

A semiconductor device according to an embodiment includes a stacking structure, a channel structure, and a plurality of gate contacts. The stacking structure includes a gate stacking structure, and the gate stacking structure includes a plurality of gate electrodes and a plurality of interlayer insulation layers. The channel structure passes through the gate stacking structure. The plurality of gate contacts passes through and is electrically connected to at least a part of the plurality of gate electrodes, respectively. Each of the plurality of gate contacts includes a conductive portion and a side insulation layer. The conductive portion includes a penetration part passing through the stacking structure and a connection part extending horizontally to have an area greater than an area of the penetration part. The side insulation layer is on a side surface of the conductive portion. The plurality of gate contacts includes a first contact. The connection part has a first surface and a second surface opposite to each other. The penetration part of the first contact includes a first portion on the first surface of the connection part and a second portion on the second surface of the connection part. The side insulation layer of the first contact is on a side surface of the first portion and is spaced apart from the second portion.

An electronic system according to an embodiment includes a main substrate, a semiconductor device on the main substrate, and a controller electrically connected to the semiconductor device on the main substrate. The semiconductor device includes a cell array region, and a connection region including a first region and a second region. The semiconductor device includes a stacking structure, a channel structure, and a plurality of gate contacts. The stacking structure includes a gate stacking structure and an insulation stacking structure. The gate stacking structure is in the cell array region and the first region, and includes a plurality of gate electrodes and a plurality of interlayer insulation layers. The insulation stacking structure is in the second region, and includes a plurality of sacrificial insulation layers and the plurality of interlayer insulation layers. The channel structure passes through the gate stacking structure in the cell array region. The plurality of gate contacts is in the second region and is electrically connected to at least a part of the plurality of gate electrodes in the first region, respectively. Each of the plurality of gate contacts includes a conductive portion and a side insulation layer. The conductive portion includes a penetration part passing through the insulation stacking structure and a connection part extending horizontally to have an area greater than an area of the penetration part. The side insulation layer is on at least a portion of a side surface of the conductive portion. The plurality of gate contacts includes a first contact. The connection part has a first surface and a second surface opposite to each other. The penetration part of the first contact includes a first portion on the first surface of the connection part and a second portion on the second surface of the connection part.

According to an embodiment, a first through portion of a through hole in which a gate contact is disposed may be formed using a first etching process including partial etching processes according to binary system, and a process of forming the gate contact may be simplified and an area of a connection region may be reduced. The gate contact may be disposed in an insulation stacking structure to be disposed in a space separated from a penetration dummy structure, and the first through portion of the through hole may be stably formed. The gate contact may include a connection part that horizontally extends, and may be easily electrically connected to a gate electrode included in a gate stacking structure. In a first contact of the gate contact, a penetration part may include a first portion on a first surface of the connection part and a second portion on a second surface of the connection part, and the first contact may be used to improve performance of a semiconductor device. Thereby, performance and reliability of a semiconductor device may be improved.

### BRIEF DESCRIPTION OF THE DRAWINGS

FIG. 1 is a partial cross-sectional view schematically illustrating a semiconductor device according to an example embodiment.

FIG. 2 is an enlarged cross-sectional view illustrating an example of a channel structure included in the semiconductor device illustrated in FIG. 1.

FIG. 3 is a plan view schematically illustrating a portion of the semiconductor device illustrated in FIG. 1.

FIG. 4 is an enlarged plan view illustrating a portion D in FIG. 3.

FIG. 5 is a cross-sectional view taken along a line E-E′ in FIG. 3.

FIG. 6 to FIG. 16 are cross-sectional views illustrating a manufacturing method of a semiconductor device according to an example embodiment.

FIG. 17 is a cross-sectional view illustrating a semiconductor device according to an example embodiment.

FIG. 18 is a cross-sectional view illustrating a semiconductor device according to an example embodiment.

FIG. 19 is a cross-sectional view illustrating a semiconductor device according to an example embodiment.

FIG. 20 is a cross-sectional view illustrating a semiconductor device according to a modified example embodiment.

FIG. 21 is a plan view schematically illustrating a semiconductor device according to an example embodiment.

FIG. 22 is a cross-sectional view of the semiconductor device illustrated in FIG. 21.

FIG. 23 is a cross-sectional view illustrating a semiconductor device according to a modified example embodiment.

FIG. 24 is a cross-sectional view illustrating a semiconductor device according to a modified example embodiment.

FIG. 25 is a cross-sectional view illustrating a semiconductor device according to a modified example embodiment.

FIG. 26 is a plan view schematically illustrating a semiconductor device according to an example embodiment.

FIG. 27 is a plan view schematically illustrating a semiconductor device according to an example embodiment.

FIG. 28 is a cross-sectional view schematically illustrating a semiconductor device according to an example embodiment.

FIG. 29 is a plan view illustrating an upper surface of a first stacking portion that is included in the semiconductor device illustrated in FIG. 28.

FIG. 30 is a plan view illustrating an upper surface of a second stacking portion that is included in the semiconductor device illustrated in FIG. 28.

FIG. 31 conceptually illustrates separation structures in the first stacking portion and the second stacking portion that are included in the semiconductor device illustrated in FIG. 28.

FIG. 32 conceptually illustrates separation structures in a plurality of gate stacking portions that are included in a semiconductor device according to an example embodiment.

FIG. 33 conceptually illustrates separation structures in a plurality of gate stacking portions that are included in a semiconductor device according to an example embodiment.

FIG. 34 is a plan view schematically illustrating a portion of a semiconductor device according to an example embodiment.

FIG. 35 is a partial cross-sectional view schematically illustrating a semiconductor device according to an example embodiment.

FIG. 36 is a partial cross-sectional view schematically illustrating a semiconductor device according to a modified example embodiment

FIG. 37 schematically illustrates an electronic system including a semiconductor device according to an example embodiment.

FIG. 38 is a perspective view schematically illustrating an electronic system including a semiconductor device according to an example embodiment.

FIG. 39 is a cross-sectional view schematically illustrating a semiconductor package according to an example embodiment.

FIG. 40 is a cross-sectional view schematically illustrating a semiconductor package according to an example embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiments provided herein. Like reference characters refer to like elements throughout.

A portion unrelated to the description is omitted in order to clearly describe the present disclosure, and same or similar components are denoted by a same reference numeral throughout the present specification.

Further, since a size and/or a thickness of a portion, a region, a member, a unit, a layer, a film, a substrate, or the like illustrated in the accompanying drawings may be arbitrarily illustrated for better understanding and convenience of explanation, the present disclosure is not limited to the illustrated size and/or thickness. In the drawings, a thickness of a portion, a region, a member, a unit, a layer, a film, a substrate, or the like may be enlarged or exaggerated for convenience of explanation and/or simple illustration

It will be understood that when a component such as a portion, a region, a member, a unit, a layer, a film, a substrate, or the like is referred to as being “on” or “above” another component, it may be directly on another component or an intervening component may also be present. In contrast, when a component is referred to as being “directly on” another component, there is no intervening component. Further, when a component is referred to as being “on” or “above” a reference component, a component may be disposed on or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains”, or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a case where a cross-section taken along a vertical direction is viewed from a side.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, the term “area” refers to a planar area.

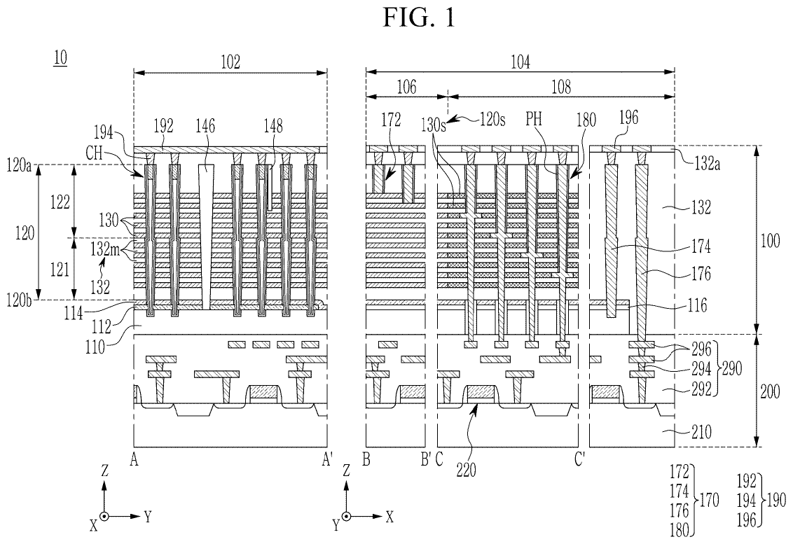

Hereinafter, referring to FIG. 1 to FIG. 16, a semiconductor device and a manufacturing method of the same according to an embodiment will be described in detail.

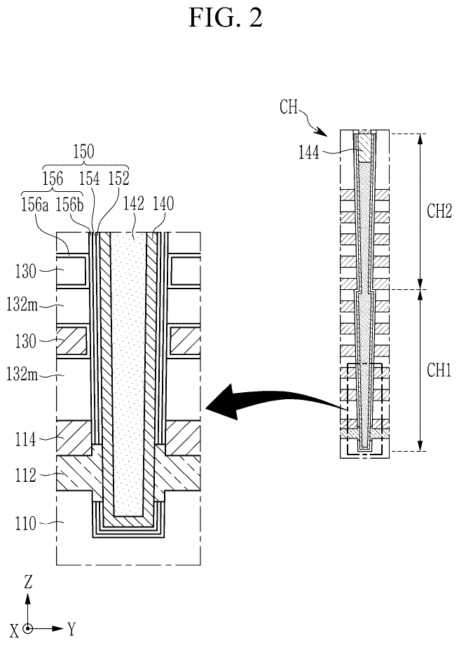

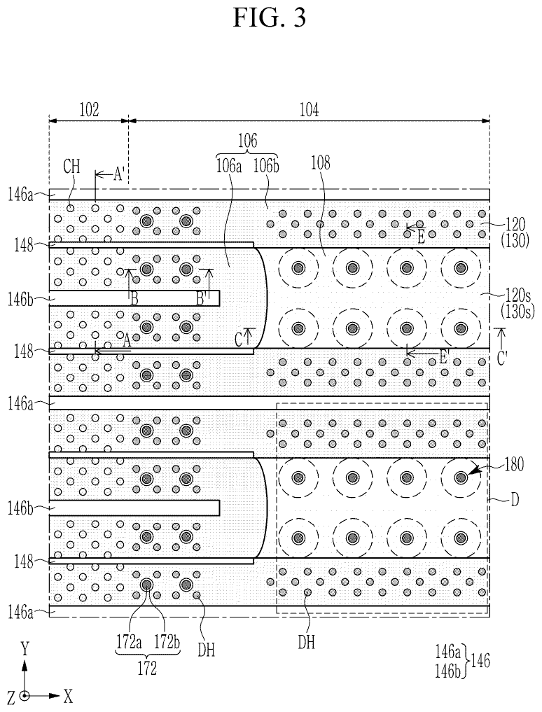

FIG. 1 is a partial cross-sectional view schematically illustrating a semiconductor device 10 according to an embodiment. FIG. 2 is an enlarged cross-sectional view illustrating an example of a channel structure CH included in the semiconductor device 10 illustrated in FIG. 1. FIG. 1 illustrates portions taken along a line A-A′, a line B-B′, and a line C-C′ in FIG. 3. For a clear understanding, in FIG. 1, positions of a source contact 174 and an input/output connection wiring 176 are conceptually illustrated.

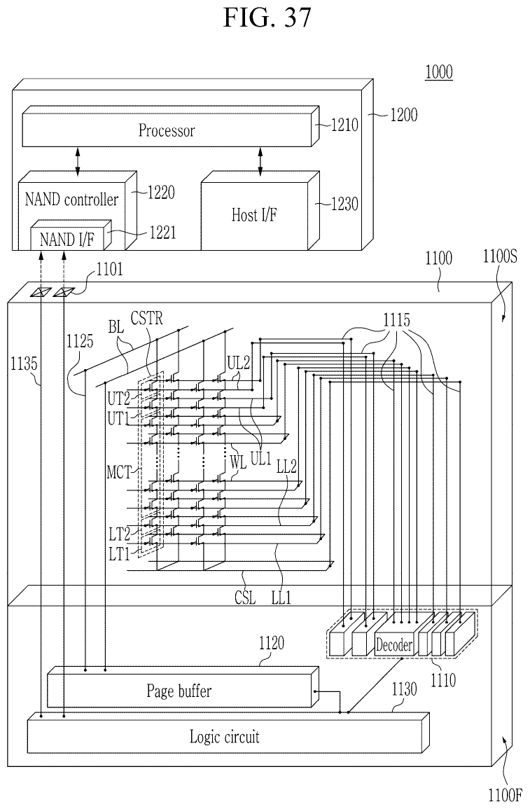

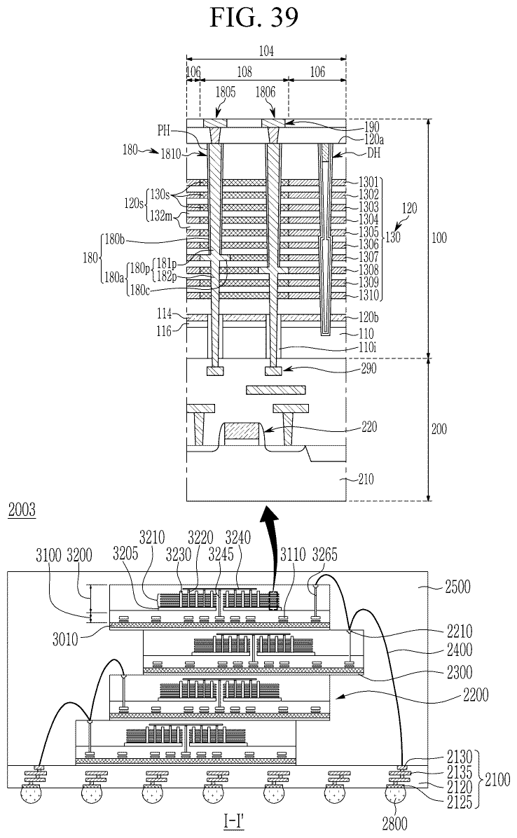

Referring to FIG. 1 and FIG. 2, a semiconductor device 10 according to an embodiment may include a cell region 100 that includes a memory cell structure and a circuit region 200 that includes a peripheral circuit structure configured to control an operation of the memory cell structure. For example, the circuit region 200 and the cell region 100 may correspond to a first structure 1100F and a second structure 1100S of a semiconductor device 1100 included in an electronic system 1000 illustrated in FIG. 37, respectively. For example, the circuit region 200 and the cell region 100 may be portions including a first structure 3100 and a second structure 3200 of a semiconductor chip 2200 illustrated in FIG. 39, respectively.

The circuit region 200 may include the peripheral circuit structure on a first substrate 210, and the cell region 100 may include a gate stacking structure 120 and a channel structure CH on a second substrate 110 as the memory cell structure. The circuit region 200 may include a circuit wiring portion 290, and the cell region 100 may include a penetration contact 170 and a cell wiring portion 190 electrically connected to the memory cell structure.

In an embodiment, the cell region 100 may be disposed on the circuit region 200. Accordingly, an area corresponding to the circuit region 200 does not need to be secured separately from the cell region 100. Therefore, an area of the semiconductor device 10 may be reduced. However, the embodiments are not limited thereto, and the circuit region 200 may be disposed next to the cell region 100. Other various modified embodiments are possible.

The circuit region 200 may include a first substrate 210, and a circuit element 220 and a circuit wiring portion 290 on a surface (an upper surface in FIG. 1) of the first substrate 210.

The first substrate 210 may be a semiconductor substrate including a semiconductor material. For example, the first substrate 210 may be a semiconductor substrate including or being formed of a semiconductor material or may be a semiconductor substrate in which a semiconductor layer is on a base substrate. For example, the first substrate 210 may include or be formed of single-crystalline or polycrystalline silicon, epitaxial silicon, germanium, silicon-germanium, silicon on insulator (SOI), germanium on insulator (GOI), or the like.

The circuit element 220 on the first substrate 210 may include any of various circuit elements that control an operation of the memory cell structure in the cell region 100. For example, the circuit element 220 may constitute the peripheral circuit structure such as a decoder circuit 1110 (refer to FIG. 37), a page buffer 1120 (refer to FIG. 37), a logic circuit 1130 (refer to FIG. 37), or the like.

The circuit element 220 may include, for example, a plurality of transistors, but the embodiments are not limited thereto. For example, the circuit element 220 may include not only an active element such as the transistor or the like but also a passive element such as a capacitor, a resistor, an inductor, or the like.

The circuit wiring portion 290 on the first substrate 210 may be electrically connected to the circuit element 220. In an embodiment, the circuit wiring portion 290 may include a plurality of wiring layers 296 that are spaced apart from each other while interposing an insulation layer 292 therebetween and are electrically connected by a contact via 294 to form a desired path. The wiring layer 296 or the contact via 294 may include any of various conductive materials, and the insulation layer 292 may include any of various insulating materials. For example, the insulation layer 292 may include or be formed of at least one of silicon oxide, silicon nitride, and silicon oxynitride.

The cell region 100 may include a cell array region 102 and a connection region 104. In the cell array region 102 and the connection region 104, a stacking structure including a gate stacking structure 120 and an insulation stacking structure 120s may be disposed on the second substrate 110. In the cell array region 102, the channel structure CH may pass through the gate stacking structure 120. A structure that connects the gate electrode 130 and/or the channel structure CH included in the gate stacking structure 120 to the circuit region 200 or an external circuit may be in the cell array region 102 and/or the connection region 104.

The gate stacking structure 120, the insulation stacking structure 120s, or the stacking structure may include a first surface 120a and a second surface 120b opposite to each other. The first surface 120a of the gate stacking structure 120, the insulation stacking structure 120s, or the stacking structure may be a surface (e.g., an upper surface in FIG. 1) adjacent to a channel pad 144 or the cell wiring portion 190 (e.g., a first wiring portion). The second surface 120b of the gate stacking structure 120, the insulation stacking structure 120s, or the stacking structure may be a surface (e.g., a lower surface in FIG. 1) opposite to the channel pad 144 or the cell wiring portion 190 (e.g., the first wiring portion).

In an embodiment, the second substrate 110 may include a semiconductor layer including a semiconductor material. For example, the second substrate 110 may be a semiconductor substrate including or being formed of a semiconductor material or may be a semiconductor substrate in which a semiconductor layer is on a base substrate. For example, the second substrate 110 may include or be formed of silicon, germanium, silicon-germanium, silicon on insulator (SOI), germanium on insulator (GOI), or the like. A p-type dopant or an n-type dopant may be doped to the semiconductor layer included in the second substrate 110. For example, the p-type dopant may include boron (B), gallium (Ga), or the like), or the n-type dopant may include phosphorus (P), arsenic (As), or the like. However, the embodiments are not limited to a material of the second substrate 110, a conductive type of the dopant doped to the semiconductor layer, or the like.

In the cell array region 102, the gate stacking structure 120 and the channel structure CH may be disposed. The gate stacking structure 120 may include cell insulation layers 132 (e.g., interlayer insulation layers 132m) and gate electrodes 130 alternately stacked on a surface (e.g., an upper surface) of the second substrate 110. The channel structure CH may extend lengthwise in a direction (e.g., a vertical direction) crossing (e.g., perpendicular to) the second substrate 110 (a Z-axis direction in the drawings) to pass through the gate stacking structure 120.

In an embodiment, horizontal conductive layers 112 and 114 may be provided between the second substrate 110 and the gate stacking structure 120 in the cell array region 102. The horizontal conductive layers 112 and 114 may electrically connect the channel structure CH and the second substrate 110. The horizontal conductive layers 112 and 114 may directly connect the channel structure CH and the second substrate 110. The horizontal conductive layers 112 and 114 may include a first horizontal conductive layer 112 and/or a second horizontal conductive layer 114 sequentially on the second substrate 110. The first horizontal conductive layer 112 may act as a portion of a common source line of the semiconductor device 10. For example, the first horizontal conductive layer 112 may act as the common source line together with the second substrate 110.

The first and second horizontal conductive layers 112 and 114 may include a semiconductor material (e.g., polycrystalline silicon). For example, the first horizontal conductive layer 112 may include a polycrystalline silicon layer including a dopant. However, the embodiments are not limited thereto, and the second horizontal conductive layer 114 may include or be formed of a material (e.g., an insulating material) different from a material of the first horizontal conductive layer 112, or the second horizontal conductive layer 114 may be omitted.

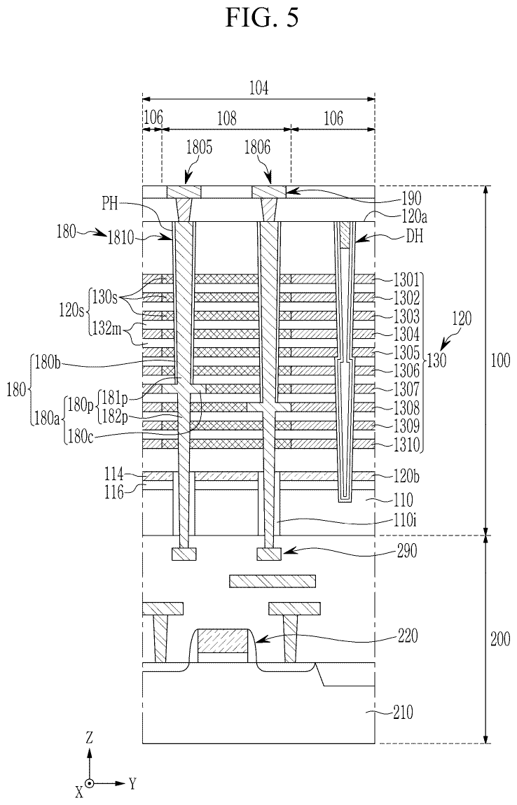

The gate stacking structure 120 where the interlayer insulation layers 132m and the gate electrodes 130 are alternately stacked on each other may be disposed on the second substrate 110 (e.g., on the first and second horizontal conductive layers 112 and 114 disposed on the second substrate 110). The gate electrode 130 may include a gate electrode (e.g., first and second gate electrodes 1301 and 1302 (refer to FIG. 5)) to which a string selection contact 172 is electrically connected, and a gate electrode (e.g., third to tenth gate electrodes 1303 to 1310 (refer to FIG. 5)) to which a gate contact 180 is electrically connected. For example, the gate electrode (e.g., the first and second gate electrodes 1301 and 1302) to which the string selection contact 172 is electrically connected may be a string selection electrode. The gate electrode 130 may further include a dummy gate electrode, a ground selection electrode, or the like.

The gate electrode 130 may include any of various conductive materials. For example, the gate electrode 130 may include or be formed of a metallic material (e.g., tungsten (W), copper (Cu), aluminum (Al), or the like), polycrystalline silicon, metal nitride (e.g., titanium nitride (TiN), tantalum nitride (TaN), or the like), or a combination thereof. As illustrated in an enlarged portion of FIG. 2, a portion (e.g., a first blocking layer 156a) of a blocking layer 156 that includes or is formed of an insulating material may be disposed outside the gate electrode 130. The interlayer insulation layer 132m may include any of various insulating materials. For example, the interlayer insulation layer 132m may include or be formed of at least one of silicon oxide, silicon nitride, silicon oxynitride, and a low dielectric constant material having a lower dielectric constant than silicon oxide, or may include or be formed of a combination thereof.

In an embodiment, the channel structure CH may be provided in the cell array region 102. The channel structure CH may extend to pass through the gate stacking structure 120 in the thickness direction of the semiconductor device 10 (e.g., the Z-axis direction in the drawings).

The channel structure CH may include a channel layer 140, and a gate dielectric layer 150 on the channel layer 140 between the gate electrode 130 and the channel layer 140. The channel structure CH may further include a core insulation layer 142 at an inside of the channel layer 140. In some embodiments, the core insulation layer 142 may be omitted. The channel structure CH may further include a channel pad 144 on the channel layer 140 and/or the core insulation layer 142. The gate dielectric layer 150 between the gate electrode 130 and the channel layer 140 may include a tunneling layer 152, a charge storage layer 154, and a blocking layer 156 sequentially on the channel layer 140.

Each channel structure CH may form one memory cell string, and a plurality of channel structures CH may be spaced apart from each other while forming rows and columns in a plan view. For example, a plurality of channel structures CH may be disposed to form any of various shapes such as a lattice shape, a zigzag shape, or the like in a plan view. The channel structure CH may have a pillar shape. For example, in a cross-sectional view, the channel structure CH may have an inclined side surface such that a width of the channel structure CH decreases toward the second substrate 110 due to a high aspect ratio. However, the embodiments are not limited thereto, and an arrangement, a structure, a shape, or the like of the channel structure CH may be variously modified.

The channel layer 140 may include a semiconductor material (e.g., polycrystalline silicon). The core insulation layer 142 may include any of various insulating materials. For example, the core insulation layer 142 may include or be formed of silicon oxide, silicon nitride, silicon oxynitride, or a combination thereof.

The tunneling layer 152 may include an insulating material that is capable of tunneling a charge (e.g., silicon oxide, silicon oxynitride, or the like). The charge storage layer 154 may be used as a data storage region, and the charge storage layer 154 may include polycrystalline silicon, silicon nitride, or the like. The blocking layer 156 may include an insulating material that is capable of preventing an undesirable flow of charge into the gate electrode 130. For example, the blocking layer 156 may include or be formed of silicon oxide, silicon nitride, silicon oxynitride, a high dielectric constant material having a higher dielectric constant than silicon oxide, or a combination thereof. In an embodiment, the blocking layer 156 may include a first blocking layer 156a that includes a portion horizontally extending on the gate electrode 130, and a second blocking layer 156b that vertically extends between the first blocking layer 156a and the charge storage layer 154. The second blocking layer 156b may contact the first blocking layer 156a and the charge storage layer 154.

However, materials, stacking structures, or the like of the channel layer 140, the core insulation layer 142, and the gate dielectric layer 150 may be variously modified, and the embodiments are not limited thereto.

The channel pad 144 may cover an upper surface of the core insulation layer 142 and be disposed to be electrically connected to the channel layer 140. The channel pad 144 may contact an upper surface of the core insulation layer 142 and side surfaces of the channel layer 140. The channel pad 144 may include a conductive material (e.g., polycrystalline silicon doped with a dopant), but the embodiments are not limited thereto.

In an embodiment, the gate stacking structure 120 may include a plurality of gate stacking portions 121 and 122 that are sequentially stacked. Thereby, a number of stacked gate electrodes 130 may increase and thus a number of memory cells may increase with a stable structure. In FIG. 1, it is illustrated as an example that the gate stacking structure 120 includes first and second gate stacking portions 121 and 122. In some embodiments, the gate stacking structure 120 may include one gate stacking portion or three or more gate stacking portions.

When the plurality of gate stacking portions 121 and 122 are provided as in the above, the channel structure CH may include a plurality of channel portions CH1 and CH2 that respectively pass through the plurality of gate stacking portions 121 and 122. The plurality of channel portions CH1 and CH2 may be connected to each other. In a cross-sectional view, each of the plurality of channel portions CH1 and CH2 may have an inclined side surface such that a width of each of the plurality of channel portions CH1 and CH2 decreases toward the second substrate 110 due to a high aspect ratio. A bent portion due to a difference in widths of the plurality of channel portions CH1 and CH2 may be provided at a boundary portion of the plurality of channel portions CH1 and CH2. In some embodiments, the plurality of channel portions CH1 and CH2 may have an inclined side surface that continuously extends without the bent portion. In FIG. 2, it is illustrated as an example that each of the gate dielectric layer 150, the channel layer 140, and the core insulation layer 142 of the plurality of channel portions CH1 and CH2 continuously extends to have an integral structure. In some embodiments, gate dielectric layers 150, channel layers 140, and core insulation layers 142 of a plurality of channel portions CH1 and CH2 may be separately formed and be electrically connected to each other. In some embodiments, a separate channel pad may be additionally disposed at the boundary portion of the plurality of channel portions CH1 and CH2. As such, the embodiments are not limited to a shape of the plurality of channel portions CH1 and CH2.

In an embodiment, the gate stacking structure 120 may be divided into a plurality of portions in a plan view by a separation structure 146. The separation structure 146 may extend to pass through or penetrate the gate stacking structure 120 in the thickness direction of the semiconductor device 10 (e.g., the Z-axis direction in the drawings). An upper separation region 148 may be disposed at an upper portion of the gate stacking structure 120. In a plan view, the separation structure 146 and/or the upper separation region 148 may extend in a first direction (an X-axis direction in the drawings). A plurality of separation structures 146 and/or a plurality of upper separation regions 148 may be spaced apart from each other at predetermined intervals in a second direction (a Y-axis direction in the drawings).

The separation structure 146 or the upper separation region 148 may include any of various insulating materials. For example, the separation structure 146 or the upper separation region 148 may include or be formed of an insulating material, such as, silicon oxide, silicon nitride, or silicon oxynitride. However, the embodiments are not limited thereto, and a structure, a shape, a material, or the like of the separation structure 146 or the upper separation region 148 may be variously modified.

The connection region 104, the penetration contact 170, and the cell wiring portion 190 may be provided to connect the gate stacking structure 120 and the channel structure CH in the cell array region 102 to the circuit region 200 or the external circuit. The connection region 104 may be disposed at a periphery of the cell array region 102, and a part of penetration contacts 170 and a portion of the cell wiring portion 190 may be disposed in the connection region 104.

The penetration contact 170 may include a string selection contact 172, a gate contact 180, a source contact 174, and an input/output connection wiring 176. The string selection contact 172 may be electrically connected to a part of the plurality of gate electrodes 130 (e.g., the first and second gate electrodes 1301 and 1302). The gate contact 180 may be electrically connected to a part of the plurality of gate electrodes 130 (e.g., the third to tenth gate electrodes 1303 to 1310). The source contact 174 may be electrically connected to the horizontal conductive layers 112 and 114 and/or the second substrate 110.

The cell wiring portion 190 may include a bit line 192, a contact via 194, and a connection wiring 196. The bit line 182 may extend in the second direction (the Y-axis direction in the drawings) that intersects (e.g., is perpendicular to) an extension direction of the gate electrode 130. The bit line 192 may be electrically connected to the channel structure CH (e.g., the channel pad 144) through the contact via 194 (e.g., a bit line contact via) that passes through the cell insulation layer 132. The contact via 194 may connect the channel structure CH to the bit line 192, or may connect the string selection contact 172, the gate contact 180, the source contact 174, or the input/output connection wiring 176 to the connection wiring 196. The connection wiring 196 may be electrically connected to the bit line 192, the string selection contact 172, the gate contact 180, the source contact 174, or the input/output connection wiring 176.

In an embodiment, the connection region 104 may include a first region 106 in which the gate stacking structure 120 is disposed and a second region 108 in which the insulation stacking structure 120s is disposed. The connection region 104 may further include a region other than the first region 106 and the second region 108.

In the connection region 104, the string selection contact 172 may pass through the gate stacking structure 120 and may be electrically connected to a part of the plurality of gate electrodes 130 (e.g., the first and second gate electrodes 1301 and 1302 that are the string gate electrodes). For example, the string selection contact 172 may pass through the gate stacking structure 120 in the first region 106 and may be electrically connected to the first and second gate electrodes 1301 and 1302 that are the string gate electrodes.

In the connection region 104, the plurality of gate contacts 180 may pass through the insulation stacking structure 120s and may be electrically connected to at least a part of the plurality of gate electrodes 130 (e.g., the third to tenth gate electrodes 1303 to 1310 that constitute word lines), respectively. For example, the gate contact 180 may pass through the insulation stacking structure 120s in the second region 108 and be electrically connected to the third to tenth gate electrodes 1303 to 1310 that constitute word lines. The gate contact 180 may be electrically connected to a side surface of the gate electrode 130 disposed in the first region 106. For example, each of the gate contacts 180 may contact a side surface of a corresponding gate electrode 130.

In the connection region 104, a penetration dummy structure DH (refer to FIG. 3) may be further disposed. The penetration dummy structure DH may relieve a stress applied to the gate stacking structure 120. For example, the penetration dummy structure DH may be disposed in the first region 106.

The first region 106 and the second region 108, the string selection contact 172, the gate contact 180, and the penetration dummy structure DH will be described later in more detail with reference to FIG. 3 to FIG. 5.

In the connection region 104, the source contact 174 may pass through the cell insulation layer 132 and be electrically connected to the horizontal conductive layers 112 and 114 and/or the second substrate 110. The input/output connection wiring 176 may pass through the gate stacking structure 120 or be disposed outside the gate stacking structure 120 to be electrically connected to the circuit wiring portion 290 of the circuit region 200.

In FIG. 1, it is illustrated as an example that the source contact 174 and/or the input/output connection wiring 176 is disposed in a region of the connection region 104 in which the cell insulation layer 132 is disposed without the gate stacking structure 120 and the insulation stacking structure 120s. However, the embodiments are not limited thereto, and the source contact 174 and/or the input/output connection wiring 176 may be disposed in the second region 108 in which the insulation stacking structure 120s is disposed.

In FIG. 1, it is illustrated as an example that the source contact 174 and/or the input/output connection wiring 176 has an inclined side surface such that a width of the source contact 174 and/or the input/output connection wiring 176 decreases toward the second substrate 110 due to an aspect ratio and a bent portion is provided at a boundary portion of the plurality of gate stacking portions 121 and 122 in a cross-sectional view. However, the embodiments are not limited thereto. In some embodiments, the source contact 174 and/or the input/output connection wiring 176 may not include the bent portion at the boundary portion of the plurality of gate stacking portions 121 and 122. Other various modified embodiments are possible.

For a clear understanding and simple illustration, it is illustrated as an example that the cell wiring portion 190 includes a single wiring layer disposed on a plane same as the bit line 192, and an insulation layer 132a is disposed in a region other the single wiring layer. However, the embodiments are not limited thereto. In some embodiments, for an electrical connection with the bit line 192, the string selection contact 172, the gate contact 180, the source contact 174 and/or the input/output connection wiring 176, the connection wiring 196 may include a plurality of wiring layers, and may further include a contact via.

The cell wiring portion 190 may be electrically connected to the circuit wiring portion 290, and therefore, the channel structure CH, the gate electrode 130, the horizontal conductive layers 112 and 114, and/or the second substrate 110 may be electrically connected to the circuit element 220 of the circuit region 200.

Referring to FIG. 3 to FIG. 5 together with FIG. 1 and FIG. 2, the first region 106 and the second region 108 that are included in the connection region 104, and the string selection contact 172, the gate contact 180, and the penetration dummy structure DH that are disposed in the connection region 104 will be described in detail.

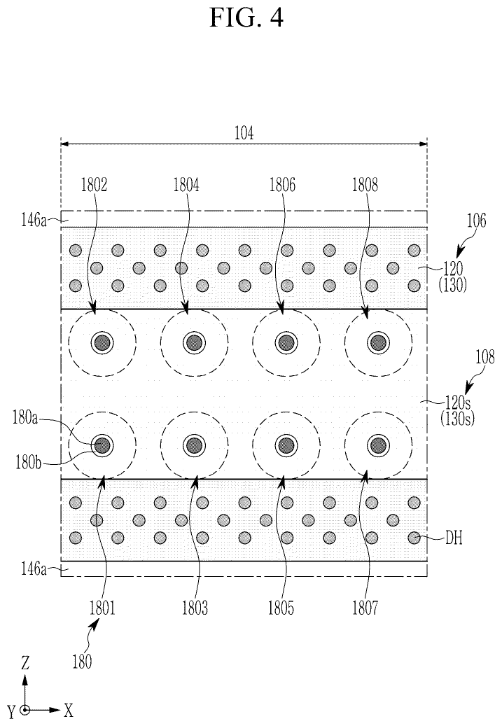

FIG. 3 is a plan view schematically illustrating a portion of the semiconductor device 10 illustrated in FIG. 1. FIG. 4 is an enlarged plan view illustrating a portion D in FIG. 3. FIG. 5 is a cross-sectional view taken along a line E-E′ in FIG. 3.

To referring FIG. 1 to FIG. 5, in an embodiment, the connection region 104 may include the first region 106 in which the gate stacking structure 120 is disposed and the second region 108 in which the insulation stacking structure 120s is disposed.

In the first region 106, the gate stacking structure 120 may be disposed on the second substrate 110 (e.g., on the horizontal conductive layers 112 and 114 disposed on the second substrate 110). Accordingly, the gate stacking structure 120 may be disposed in the cell array region 102 and the first region 106.

In the second region 108, the insulation stacking structure 120s may be disposed on the second substrate 110 (e.g., on the horizontal conductive layers 112 and 114 and/or the horizontal insulation layer 116 disposed on the second substrate 110).

The insulation stacking structure 120s may include a plurality of cell insulation layers 132 (e.g., a plurality of interlayer insulation layers 132m) and a plurality of sacrificial insulation layers 130s that are alternately stacked on each other. In the insulation stacking structure 120s, the plurality of sacrificial insulation layers 130s may be disposed to correspond to the plurality of gate electrodes 130, respectively. The plurality of interlayer insulation layers 132m of the insulation stacking structure 120s may be disposed to correspond to the interlayer insulation layer 132m of the gate stacking structure 120, respectively. The sacrificial insulation layer 130s may include a material different from a material of the cell insulation layer 132 (e.g., the interlayer insulation layer 132m). For example, the sacrificial insulation layer 130s may include or be formed of silicon, silicon oxide, silicon carbide, silicon nitride, silicon oxynitride (SiONx), or the like, and may include a material different from a material of the cell insulation layer 132 (e.g., the interlayer insulation layer 132m).

The plurality of interlayer insulation layers 132m of the gate stacking structure 120 and the plurality of interlayer insulation layers 132m of the insulation stacking structure 120s may be insulation layers formed by a same process. In the cell array region 102, the first region 106 and the second region 108, the plurality of interlayer insulation layers 132m and the plurality of sacrificial insulation layers 130s may be alternately stacked to form the insulation stacking structure 120s. After that, the plurality of sacrificial insulation layers 130s that are disposed in the cell array region 102 and at least a portion of the first region 106 may be selectively removed, and the gate electrode 130 may be formed in portions in which the sacrificial insulation layers 130s are removed. Accordingly, in the cell array region 102 and at least a portion of the first region 106, the gate stacking structure 120 in which the plurality of interlayer insulation layers 132m and the plurality of gate electrodes 130 are alternately stacked on each other may be disposed. In the second region 108, the insulation stacking structure 120s in which the plurality of interlayer insulation layers 132m and the plurality of sacrificial insulation layers 130s are alternately stacked on each other may remain.

The separation structure 146 may include a first separation structure 146a and a second separation structure 146b. The first separation structure 146a may extend in the first direction (the X-axis direction in the drawings) to correspond to the cell array region 102, the first region 106, and the second region 108. The second separation structure 146b may be disposed between the plurality of first separation structures 146a (e.g., between two adjacent first separation structures 146a) and may extend to have a length smaller than a length of the first separation structure 146a in the first direction. For example, the second separation structure 146b may be disposed to correspond to a portion in which the second region 108 is disposed in the second direction (the Y-axis direction in the drawings), and may be spaced apart from the second region 108 in the first direction. In the process of replacing the sacrificial insulation layer 130s with the gate electrode 130, the sacrificial insulation layer 130s may remain in a portion spaced apart from the first separation structure 146a and the second separation structure 146b. A remained portion of the sacrificial insulation layer 130s may constitute the second region 108.

For example, in the first direction (the X-axis direction in the drawings), the first separation structure 146a may have a length greater than a length of the upper separation region 148. In FIG. 4, it is illustrated as an example that the second separation structure 146b has a length less than a length of the upper separation region 148, but the second separation structure 146b may have a length same as or greater than a length of the upper separation region 148.

The first region 106 may include a first area 106a and a second area 106b. In the first area 106a, the first separation structure 146a and the second separation structure 146b may be disposed together. In the second area 106b, the first separation structure 146a may be disposed without the second separation structure 146b.

The first area 106a may be disposed between the first separation structure 146a and the second separation structure 146b, between adjacent first separation structures 146a, or between adjacent second separation structures 146b in the second direction (the Y-axis direction in the drawings). That is, in the second direction, two adjacent first area 106a may be disposed while interposing the first separation structure 146a or the second separation structure 146b.

The second areas 106b may be adjacent to two adjacent first separation structures 146a, respectively, in the second direction (the Y-axis direction in the drawings), and two second area 106b that is adjacent to two adjacent first separation structures 146a may be disposed while interposing the second region 108. For example, two first regions 106 (i.e., two second areas 106b) may be adjacent to two adjacent first separation structures 146a, respectively, in the second direction (the Y-axis direction in the drawings), and the two first regions 106 (i.e., the two second areas 106b) that are adjacent to the two adjacent first separation structures 146a may be disposed while interposing the second region 108.

The second region 108 may be disposed between two adjacent first separation structures 146a in the second direction (the Y-axis direction in the drawings), and may be spaced apart from the second separation structure 146b in the first direction (the X-axis direction in the drawings). That is, the second region 108 may be spaced apart from the second separation structure 146b between two adjacent first separation structures 146a.

In an embodiment, by using the first separation structure 146a and the second separation structure 146b having different lengths, the connection region 104 that includes the first region 106 and the second region 108 may be easily formed.

The string selection contact 172 may be disposed in the first region 106 (e.g., the first area 106a), and the gate contact 180 may be disposed in the second region 108. In the first region 106 (e.g., the first area 106a and/or the second area 106b), the penetration dummy structure DH may be disposed. For example, the penetration dummy structure DH may be disposed at a periphery of the string selection contact 172 in the first area 106a, and may be disposed in the second area 106b.

In FIG. 3 and FIG. 5, it is illustrated as an example that the penetration dummy structure DH and the channel structure CH are formed by a same process and have a same structure, material, or the like, and the penetration dummy structure DH has a planar shape and an area (e.g., a planar area) same as a planar shape and an area of the channel structure CH. The penetration dummy structure DH may not be electrically connected to the bit line 192. Thereby, a manufacturing process may be simplified. Further, the penetration dummy structure DH may have a property same as a property of the channel structure CH, and the separation structure 146 may be stably formed. However, the embodiments are not limited thereto. In some embodiments, the penetration dummy structure DH may be formed by a process different from a process of forming the channel structure CH, and may have a structure, a material, a planar shape, an area, or the like different from a structure, a material, a planar shape, an area, or the like of the channel structure CH.

In FIG. 3, it is illustrated as an example that a plurality of penetration dummy structures DH are disposed to form a rectangular shape at a periphery of the string selection contact 172 in the first area 106a and are disposed to form a zigzag shape in the second area 106b. However, the embodiments are not limited thereto, and an arrangement of the penetration dummy structure DH may be variously modified. In some embodiments, at least a portion of the penetration dummy structure DH may be disposed across an edge of the gate electrode 130 and may reach or be in contact the separation structure 146. Other various modified embodiments are possible.

In an embodiment, the penetration dummy structure DH may be disposed in the first region 106 (e.g., the first area 106a and/or the second area 106b), and the gate contact 180 may be disposed in the second region 108. Accordingly, the penetration dummy structure DH may be disposed independently in a space separated from the gate contact 180. That is, the penetration dummy structure DH may be disposed in the first region 106 (e.g., the first area 106a and/or the second area 106b) to be separated from the gate contact 180 disposed in the second region 108. Thereby, a process of forming the gate contact 180 may be easily performed and a stability of the gate contact 180 may be enhanced.

On the other hand, in a comparative example in which a gate contact is adjacent to or overlaps a penetration dummy structure, in a process of forming a through hole for a gate contact, a portion in which the penetration dummy structure is disposed and a portion in which the penetration dummy structure is not disposed may be removed together. Accordingly, it may be difficult to form the through hole accurately at a desired position.

As described in the above, in an embodiment, the string selection contact 172 may be disposed in the first region 106 (e.g., the first area 106a), and may be discriminated from the gate contact 180 disposed in the second region 108. Further, the string selection contact 172 may have a shape or a structure different from a shape or a structure of the gate contact 180. A shape of the gate contact 180 will be described in detail and a shape of the string selection contact 172 will be described in detail.

In an embodiment, the plurality of gate contacts 180 may be disposed in the second region 108 in which the insulation stacking structure 120s is disposed, and may be electrically connected to at least a part of the plurality of gate electrodes 130 (e.g., third to tenth gate electrodes 1303 to 1310) disposed in the first region 106, respectively. For example, a side surface of a connection part 180c of the gate contact 180 that is disposed in the second region 108 may be electrically connected to a side surface of the gate electrode 130 that is disposed in the first region 106. For example, a side surface of a connection part 180c of the gate contact 180 that is disposed in the second region 108 may contact a side surface of the gate electrode 130 that is disposed in the first region 106.

Each of the plurality of gate contacts 180 may include a conductive portion 180a and a side insulation layer 180b. The conductive portion 180a may include a penetration part 180p and a connection part 180c. The penetration part 180p may pass through the insulation stacking structure 120s, and the connection part 180c may extend horizontally to have an area greater than an area of the penetration part 180p. The side insulation layer 180b may be disposed on a side surface of at least a portion of the conductive portion 180a. In a plan view, the connection part 180c may have a shape that protrudes from the penetration part 180p.

The penetration part 180p may extend in the thickness direction of the semiconductor device 10 (the Z-axis direction in the drawings) to pass through the insulation stacking structure 120s, and the connection part 180c may horizontally extend to have an area greater than an area of the penetration part 180p. The penetration part 180p may be spaced apart from the first region 106, and the connection part 180c may horizontally extend to be connected to (e.g., to be in contact with) the gate electrode 130 disposed in the first region 106. For example, the connection part 180c may extend horizontally to contact a side surface of a corresponding gate electrode 130. For example, the connection part 180c may have a flange shape.

For example, the conductive portion 180a may include or be formed of tungsten (W), copper (Cu), aluminum (Al), or the like, and may further include a diffusion barrier layer. However, the embodiments are not limited to a material of the conductive portion 180a. For example, the side insulation layer 180b may include or be formed of oxide (e.g., silicon oxide), oxynitride (e.g., silicon oxynitride), a low dielectric constant material having a lower dielectric constant than silicon oxide, or a combination thereof. The side insulation layer 180b may include a single layer or a plurality of layers. However, the embodiments are not limited thereto, and the conductive portion 180a or the side insulation layer 180b may include any of various materials.

The plurality of gate contacts 180 (e.g., the plurality of connection parts 180c included in the plurality of gate contacts 180) may be connected to the plurality of gate electrodes 130, respectively. In the thickness direction of the semiconductor device 10 (the Z-axis direction in the drawings), the plurality of gate electrodes 130 may be disposed at different heights or different levels, and the plurality of connection parts 180c of the plurality of gate contacts 180 may be disposed at different heights or different levels. At least a portion of the penetration part 180p (e.g., a portion of the penetration part 180p on a first surface of the connection part 180c) may pass through a portion of the gate stacking structure 120 such that the connection part 180c of the gate contact 180 is electrically connected to a connection gate electrode.

For example, a first gate contact 1801 (e.g., a connection part 180c included in the first gate contact 1801) may be electrically connected to the third gate electrode 1303. An n-th gate contact (e.g., a connection part 180c included in the n-th gate contact) may be electrically connected to an (n+2)-th gate electrode. In the drawings, it is illustrated as an example that the gate electrode 130 electrically connected to the gate contact 180 includes the third to tenth gate electrodes 1303 to 1310. In this instance, first to eighth gate contacts 1801 to 1808 may be electrically connected to the third to tenth gate electrodes 1303 to 1310, respectively. Accordingly, the plurality of gate contacts 180 may be electrically connected to the plurality of gate electrodes 130, respectively.

Based on one gate contact 180, a plurality of gate electrodes 130 may include a connection gate electrode electrically connected to one gate contact 180, and may include a penetration gate electrode and/or a remaining gate electrode. The penetration gate electrode may refer to a gate electrode 130 disposed above the connection gate electrode and penetrated by the gate contact 180. The penetration gate electrode may include the string selection electrode. The remaining gate electrode refers to a gate electrode 130 below the connection gate electrode. The remaining gate electrode may be penetrated by the gate contact 180, or may not be penetrated by the gate contact 180.

In an embodiment, a plurality of through holes PH may individually pass through the insulation stacking structure 120s and be spaced apart from each other while interposing the insulation stacking structure 120s. Each of the gate contacts 180 may be disposed in a corresponding one of the through holes PH. The side surface of the connection part 180c of the gate contact 180 in each gate contact 180 in each through hole PH may be connected to (e.g., be in contact with) the side surface of the gate electrode 130. In some embodiments, the plurality of gate contacts 180 may be respectively disposed in the plurality of through holes PH that are spaced apart from each other to one-to-one correspond to the plurality of gate contacts 180. In an embodiment, a portion of the through hole PH may have any of various planar shapes, such as, a circular shape, a polygon shape, an oval shape, or the like, but the embodiments are not limited to a planar shape of the through hole PH.

In an embodiment, in the first region 106 (e.g., the first area 106a and/or the second area 106b), the gate stacking structure 120 may be disposed in the entirety of a portion other than the separation structure 146 and the upper separation region 148. For example, in the first region 106 (e.g., the first area 106a and/or the second area 106b), extension lengths of the plurality of gate electrodes 130 may be substantially same. Substantially same may refer to have a difference within a process error (e.g., less than 10%). In an embodiment, a portion (e.g., a pad region) in which the gate stacking structure 120 is removed to have a stair shape for an electrical connection between the gate electrode 130 and the gate contact 180 or an insulation layer (e.g., a pad insulation layer) in the portion may not be provided. That is, without the pad region or the pad insulation layer, the plurality of gate electrodes 130 may be individually electrically connected to the plurality of gate contacts 180, respectively. Accordingly, a process of electrically connecting the gate contact 180 and the gate electrode 130 may be simplified, and an area of the connection region 104 may be reduced.

On the other hand, in a comparative example including a pad region, a process of etching a gate stacking structure (e.g., a process of forming a portion of a stair shape), a process of forming a pad insulation layer covering the gate stacking structure, a process of electrically connecting a plurality of gate contacts that pass through one pad insulation layer to a plurality of gate electrodes, respectively. Accordingly, the process of forming the pad region and the process of forming the gate contact may be complicated. In the pad region or the pad insulation layer through which the plurality of gate contacts pass, an interval between the plurality of gate contacts may be large to prevent a mis-alignment of the gate contact. Accordingly, an area of a connection region may be large.

In an embodiment, the plurality of connection parts 180c that are included in the plurality of gate contacts 180 adjacent to each other in the first direction (the X-axis direction in the drawings) may be disposed while interposing at least one sacrificial insulation layer 130s in the thickness direction of the semiconductor device 10 (the Z-axis direction in the drawings). Thereby, at least one sacrificial insulation layer 130s may be disposed between the plurality of connection parts 180c that are included in the plurality of gate contacts 180 adjacent to each other in the first direction, thereby improving a physical stability and an electrical stability.

This may be because a distance between the plurality of gate contacts 180 in the second direction (the Y-axis direction in the drawings) may be greater than a distance between the plurality of gate contacts 180 in the first direction (the X-axis direction in the drawings). However, the embodiments are not limited thereto, and the distance between the plurality of gate contacts 180 in the second direction may be same as or less than the distance between the plurality of gate contacts 180 in the first direction.

For example, in FIG. 4, it is illustrated as an example that a first gate contact 1801, a third gate contact 1803, a fifth gate contact 1805, and a seventh gate contact 1807 are disposed in a first row in the second direction (the Y-axis direction in the drawings), and a second gate contact 1802, a fourth gate contact 1804, a sixth gate contact 1806, and an eighth gate contact 1808 are disposed in a second row in the second direction. The first gate contact 1801, the third gate contact 1803, the fifth gate contact 1805, and the seventh gate contact 1807 may be sequentially disposed in the first direction. The second gate contact 1802, the fourth gate contact 1804, the sixth gate contact 1806, and the eighth gate contact 1808 may be sequentially disposed in the first direction. However, the embodiments are not limited thereto. In the second direction, one row in which the gate contacts 180 are disposed may be included, or three or more rows in which the gate contacts 180 are disposed, respectively, may be included. An arrangement of the plurality of gate contacts 180 may be variously modified.

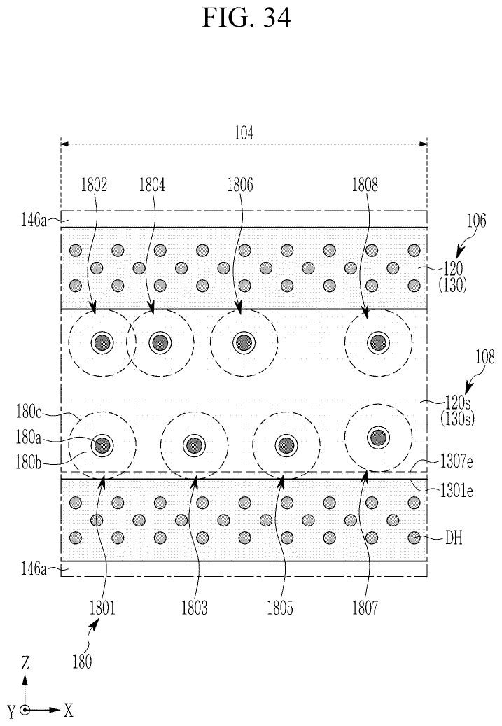

In FIG. 4, it is illustrated as an example that the first gate contact 1801, the third gate contact 1803, the fifth gate contact 1805, and the seventh gate contact 1807 are disposed at a first position in the second direction (the Y-axis direction in the drawings) and are disposed to have a same interval in the first direction. In FIG. 4, it is illustrated as an example that the second gate contact 1802, the fourth gate contact 1804, the sixth gate contact 1806, and the eighth gate contact 1808 are disposed at a second position in the second direction and are disposed to have a same interval in the first direction. However, the embodiments are not limited thereto. Referring to FIG. 34, an embodiment will be described later in detail.

In FIG. 4, it is illustrated as an example that the plurality of connection parts 180c included in the plurality of gate contacts 180 adjacent each other in each of the first direction (the X-axis direction in the drawings) and the second direction (the Y-axis direction in the drawings) do not overlap each other. However, the embodiments are not limited thereto, and the plurality of connection parts 180c included in the plurality of gate contacts 180 adjacent each other in the first direction and/or the second direction may be disposed to partially overlap each other. In this instance, the plurality of connection parts 180c may be electrically insulated from each other by the interlayer insulation layer 132m and/or the sacrificial insulation layer 130s between the plurality of connection parts 180c. Thereby, a distance between the plurality of gate contacts 180 may be reduced, and an area of the connection region 104 may be reduced.

In an embodiment, the plurality of gate contacts 180 may include a first contact 1810.

In the first contact 1810, the penetration part 180p may include a first portion 181p on a first surface (an upper surface in FIG. 5) of the connection part 180c and a second portion 182p on a second surface (a lower surface in FIG. 5) of the connection part 180c. The first surface of the connection part 180c and the second surface of the connection part 180c may be opposite to each other. The first portion 181p and the second portion 182p of the penetration part 180p may be disposed on opposite surfaces while interposing the connection part 180c. In the first contact 1810, the side insulation layer 180b may be disposed on the side surface of the first portion 181p and may be spaced apart from the second portion 182p. That is, the side insulation layer 180b may be disposed on a side surface of the first portion 181p, and may not disposed on a side surface of the second portion 182p.

The connection part 180c may be disposed between the first portion 181p and the second portion 182p, and may have an area (e.g., a planar area) greater than an area (e.g., a planar area) of the first portion 181p and an area (e.g., a planar area) of the second portion 182p. For example, when viewed in cross-section, a horizontal width of the connection part 180c may be greater than a horizontal width of the first portion 181p and a horizontal width of the second portion 182p.

The first portion 181p may extend in the thickness direction of the semiconductor device 10 (the Z-axis direction in the drawings). The first portion 181p may extend from the first surface 120a (an upper surface in FIG. 5) of the stacking structure (e.g., the insulation stacking structure 120s) to the first surface of the connection part 180c.

The second portion 182p may extend in the thickness direction of the semiconductor device 10 (the Z-axis direction in the drawings). The second portion 182p may extend from the second surface of the connection part 180c to the second surface 120b of the stacking structure (e.g., the insulation stacking structure 120s).

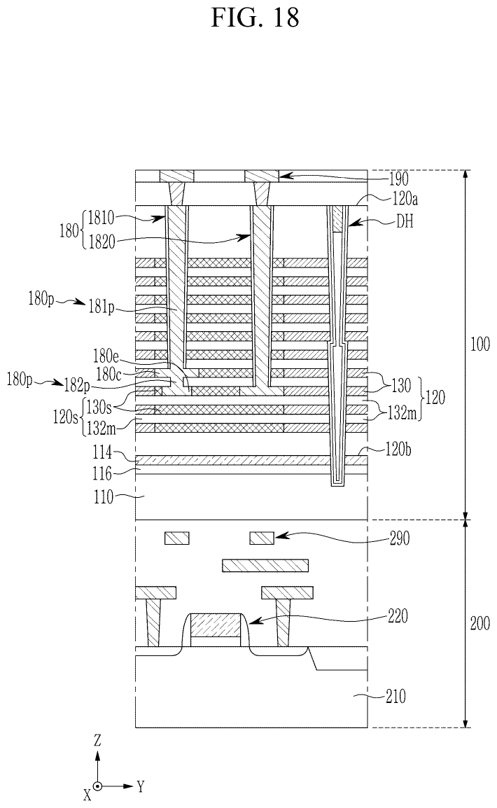

The penetration part 180p of the first contact 1810 may include the first portion 181p and the second portion 182p, and the first portion 181p and the second portion 182p of the penetration part 180p may be contributed to improve performance of the semiconductor device 10. In some embodiments, the first contact 1810 may be a first connection contact that is electrically connected to a first wiring portion and a second wiring portion on opposite sides of the stacking structure, and freedom of a wiring included in the semiconductor device 10 may be improved. In some embodiments, in a portion (e.g., the second portion 182p) of the penetration part 180p, an expanded portion 180e (refer to FIG. 18 to FIG. 20) configured to relieve a stress applied to the semiconductor device 10 may be disposed. Referring to FIG. 18 to FIG. 20, this will be described later in detail.

In an embodiment, the first contact 1810 may be electrically connected to the first wiring portion (e.g., the cell wiring portion 190) on the first surface 120a of the stacking structure (e.g., the insulation stacking structure 120s) through the first portion 181p, and may be electrically connected to the second wiring portion (e.g., the circuit wiring portion 290) on the second surface 120b of the stacking structure (e.g., the insulation stacking structure 120s) through the second portion 182p. That is, the first contact 1810 may be the first connection contact that is electrically connected to the first wiring portion and the second wiring portion on opposite sides of the stacking structure.

The first connection contact may pass through the entirety of the insulation stacking structure 120s and be electrically connected to the first wiring portion and the second wiring portion, and may be referred to as a through cell gate contact.

When the first contact 1810 is the first connection contact, voltages or signals may be applied to opposite sides of the gate contact 180. Thereby, freedom of the wiring included in the semiconductor device 10 may be improved.

For example, the conductive portion 180a of the first contact 1810 may be a base contact that includes the penetration part 180p and the connection part 180c and does not include an expanded portion. When the first contact 1810 is the base contact, a manufacturing process may be simplified.

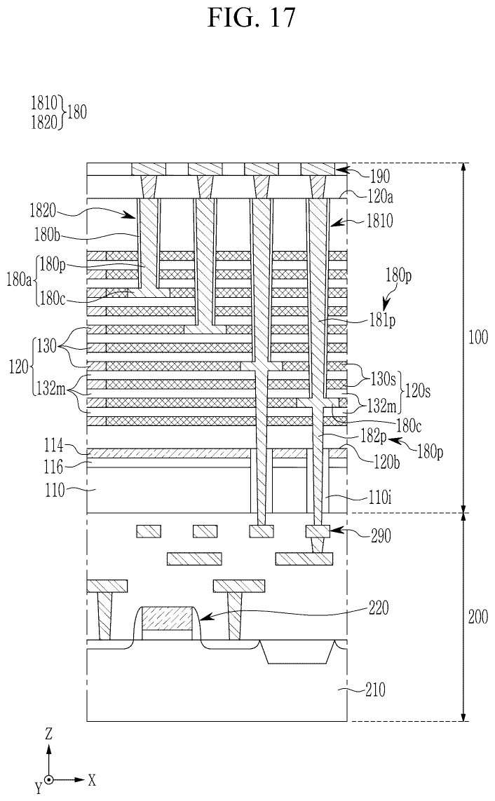

In FIG. 5, it is illustrated as an example that the plurality of gate contacts 180 includes the plurality of first contacts 1810, and each of the plurality of first contacts 1810 is the first connection contact and the base contact. However, the embodiments are not limited thereto. The plurality of gate contacts 180 may further include a contact having a structure or a shape different from a structure or a shape of the first contact 1810, or the first contact 1810 may include a second connection contact different from the first connection contact, an expanded contact other than the base contact, or the like. Referring to FIG. 17 to FIG. 20, this will be described later in detail.

In FIG. 5, it is illustrated as an example that a penetration insulation portion 110i passes through the second substrate 110 and/or the horizontal conductive layers 112 and 114, and the second portion 182p of the first contact 1810 passes through the penetration insulation portion 110i to be electrically connected to the circuit region 200. The penetration insulation portion 110i may include any of various insulating materials. However, the embodiments are not limited thereto, and an electrical connection structure between the second portion 182p of the first contact 1810 and the circuit region 200 may be variously modified.

The side insulation layer 180b may be disposed on the side surface of the first portion 181p, and may not be disposed on the side surface of the connection part 180c and the side surface of the second portion 182p. For example, the side insulation layer 180b may surround the side surface of the first portion 181p. The side insulation layer 180b may protect a portion of the insulation stacking structure 120s around the first portion 181p in a process of forming the connection part 180c. However, the embodiments are not limited thereto, and a position or the like of the side insulation layer 180b may be variously modified.

For example, the penetration part 180p (e.g., the first portion 181p and/or the second portion 182p) may have a pillar shape (e.g., a pillar shape having a planar shape or a circular shape or a polygonal shape), and the side insulation layer 180b may have any of various planar shapes such as an annular shape, a ring shape, a frame shape, or the like to surround the first portion 181p.

In the drawings, it is illustrated as an example that the penetration part 180p (e.g., the first portion 181p and/or the second portion 182p) may have an inclined side surface in a cross-sectional view such that a width of the penetration part 180p decreases toward the second substrate 110 due to a high aspect ratio. However, the embodiments are not limited thereto, and a shape, a structure, or the like of the penetration part 180p may be variously modified.

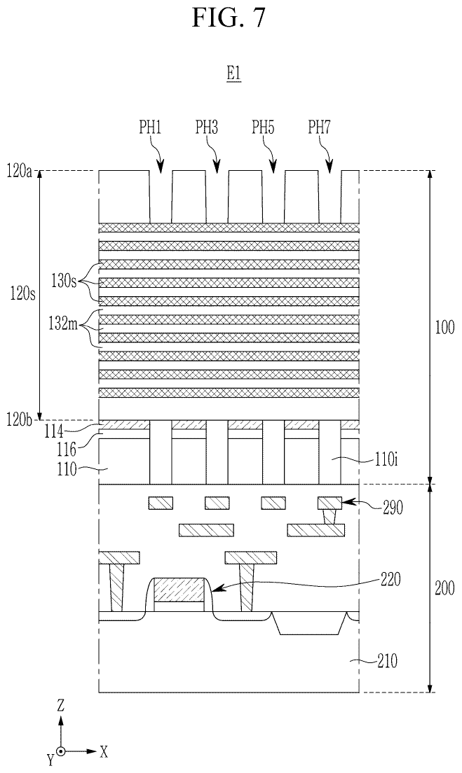

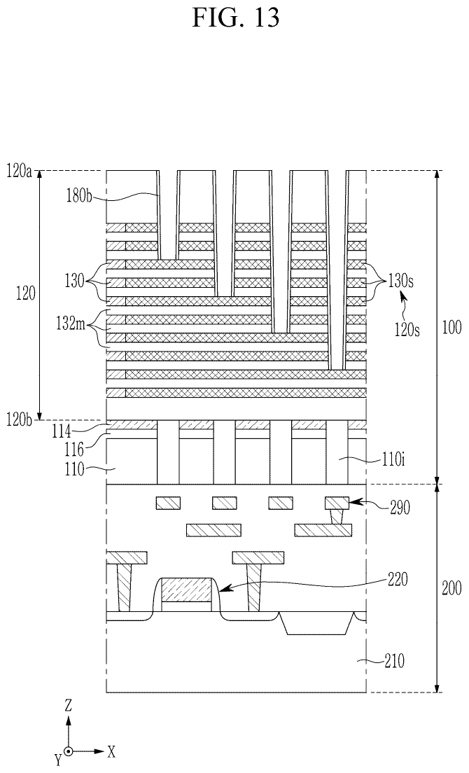

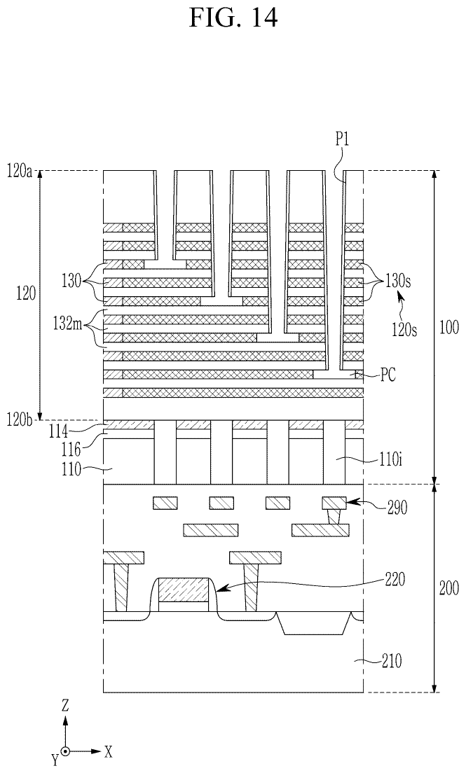

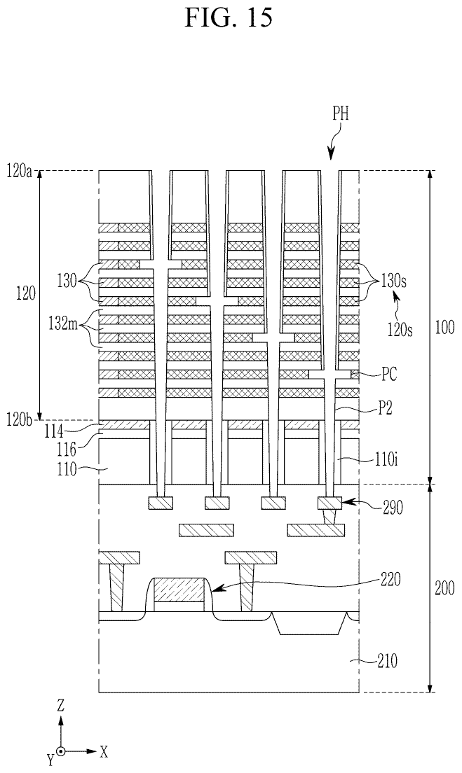

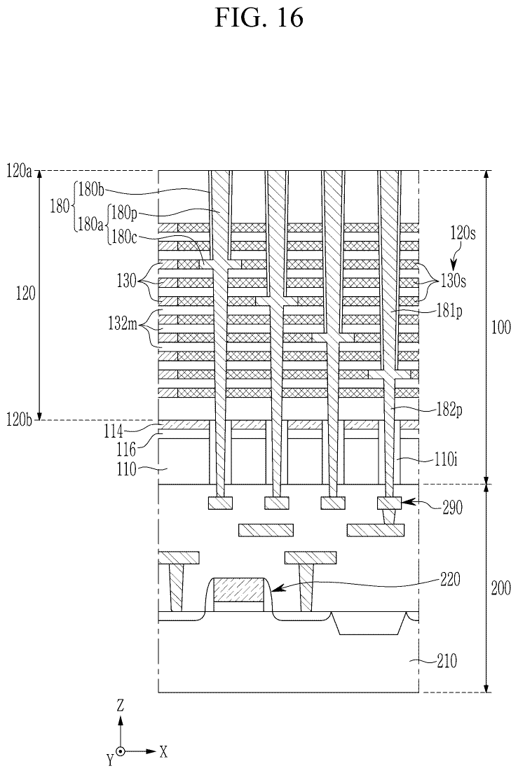

In an embodiment, the gate contact 180 may formed by a process including a plurality of partial etching processes using binary system. For example, a process of forming the first contact 1810 may include a first etching process (refer to FIG. 7 to FIG. 10), a process of forming the side insulation layer 180b (refer to FIG. 13), a process of forming a connection through portion of the through hole PH (refer to FIG. 14), a second etching process (refer to FIG. 15), and a process of forming the conductive portion 180a (refer to FIG. 16). In the first etching process, a first through portion of the through hole PH may be formed in a portion in which the first portion 181p will be formed. In the process of forming the side insulation layer 180b, the side insulation layer 180b may be formed on a side surface of the first through portion of the through hole PH. In the process of forming the connection through portion of the through hole PH, the connection through portion of the through hole PH may be formed in a portion in which the connection part 180c will be disposed. In the second etching process, a second through portion of the through hole PH may be formed in a portion in which the second portion 182p will be formed. The first etching process may include the plurality of partial etching processes using the binary system.

By repeatedly performing the partial etching processes according to the binary system as in the above, a plurality of first through portions having different depths may be formed by a small number of etching processes. For example, when the partial etching processes according to the binary system are repeated four times, fifteen first through portions having different depths may be formed. For example, when the partial etching processes according to the binary system are repeated five times, thirty-one first through portions having different depths may be formed. For example, when the partial etching processes according to the binary system are repeated six times, sixth-three first through portions having different depths may be formed. Thereby, a number of etching processes may be effectively reduced. A number of the plurality of partial etching processes may be variously modified according to a number of the gate electrodes 130, and, in some embodiments, an additional etching process may be further performed to have a predetermined depth after the plurality of partial etching processes.

The process of forming the gate contact 180 (e.g., the first contact 1810) will be described in detail in a manufacturing method of a semiconductor device 10.

In an embodiment, the string selection contact 172 may be disposed in the first region 106 (e.g., the first area 106a). The string selection contact 172 may include a conductive portion 172a passing through the gate stacking structure 120, and a side insulation layer 172b disposed on a side surface of the conductive portion 172a. The conductive portion 172a may correspond to the first portion 181p of the first contact 1810, and the side insulation layer 172b may be disposed on the entirety of a side surface of the conductive portion 172a. Accordingly, the string selection contact 172 may not include a portion in which the side insulation layer 172b is not disposed (e.g., a portion corresponding to the second portion 182p of the first contact 1810) and a portion corresponding to a portion (e.g., the connection part 180c of the gate contact 180) that horizontally extends.

The string selection contact 172 or the conductive portion 172a included therein may extend downward from the first surface 120a of the gate stacking structure 120 toward the second surface 120b, and may pass through a portion of the gate stacking structure 120 in the thickness direction of the semiconductor device 10 (the Z-axis direction in the drawings). For example, the string selection contact 172 or the conductive portion 172a included therein may be electrically connected to an upper surface of the string selection electrode (e.g., the first or second gate electrodes 1301 or 1302). For example, the string selection contact 172 or the conductive portion 172a included therein may contact an upper surface of the string selection electrode (e.g., the first or second gate electrodes 1301 or 1302). However, the embodiments are not limited thereto. Each string selection contact 172 may be electrically connected to another portion (e.g., a side surface) of the string selection electrode (e.g., the first or second gate electrodes 1301 or 1302). For example, each string selection contact 172 may contact another portion of the string selection electrode (e.g., the first or second gate electrodes 1301 or 1302).

For example, the plurality of string selection contacts 172 may be connected to the plurality of string selection electrodes (e.g., the first and second gate electrodes 1301 and 1302), respectively. In the thickness direction of the semiconductor device 10 (the Z-axis direction in the drawings) (e.g., in the vertical direction), the plurality of string selection electrodes (e.g., the first and second gate electrodes 1301 and 1302) may be disposed at different heights or different levels, and the plurality of string selection contacts 172 may have different depth to reach the plurality of string selection electrodes, respectively. For example, a first string selection contact may be electrically connected to a first string selection electrode (e.g., the first gate electrode 1301), and a second string selection contact may be electrically connected to a second string selection electrode (e.g., the second gate electrode 1302).

In the drawings and the description, it is illustrated and described as an example that two string selection gates and two string selection contacts 172 are included. However, the string selection gate may include one, or three or more string selection gates, and the string selection contact 172 may include one or a plurality of string selection contacts electrically connected to one, or three or more string selection gates, respectively.

In an embodiment, a process of forming the string selection contact 172 may include an etching process of forming the through hole PH, a process of forming the side insulation layer 172b, and a process of forming the conductive portion 172a. In the etching process of forming the through hole PH, the through hole PH may be formed in a portion where the conductive portion 172a will be formed. In the process of forming the side insulation layer 172b, the side insulation layer 172b may be formed on a side surface of the through hole PH. That is, the process of forming the string selection contact 172 may not include the process of forming the connection through portion of the through hole PH and the second etching process.

In an embodiment, the through hole PH in which the string selection contact 172 will be disposed may be formed using at least a part of the first etching process of forming the gate contact 180, or may be formed using an additional etching process separately performed from the first etching process of forming the gate contact 180. For example, the additional etching process may be performed before the first etching process or after the first etching process. The side insulation layer 172b of the string selection contact 172 may be formed using at least a part of the process of forming of the side insulation layer 180b of the gate contact 180, or may be formed using an additional process separately performed from the process of forming of the side insulation layer 180b of the gate contact 180. The conductive portion 172a of the string selection contact 172 may be formed using at least a part of the process of forming of the conductive portion 180a of the gate contact 180, or may be formed using an additional process separately performed from the process of forming of the conductive portion 180a of the gate contact 180.

According to an embodiment, the first through portion of the gate contact 180 may be formed using the first etching process including the partial etching processes according to the binary system, and the process of forming the gate contact 180 may be simplified and the area of the connection region 104 may be reduced. The gate contact 180 may be disposed in the insulation stacking structure 120s to be disposed in a space separated from the penetration dummy structure DH, and the first through portion of the through hole PH may be stably formed. For example, if a process error may be undesirably induced in the process of forming the first through portion of the through hole PH, the gate contact 180 may be disposed in the insulation stacking structure 120s and thus an unwanted electrical short circuit may be prevented or minimized. The gate contact 180 may include the connection part 180c that horizontally extends, and may be easily electrically connected to the gate electrode 130 included in the gate stacking structure 120. In the first contact 1810 of the gate contact 180, the penetration part 180p may include the first portion 181p and the second portion 182p on the first surface and the second surface of the connection part 180c, respectively, and may be used to improve performance of the semiconductor device 10. Thereby, performance and reliability of the semiconductor device 10 may be improved.

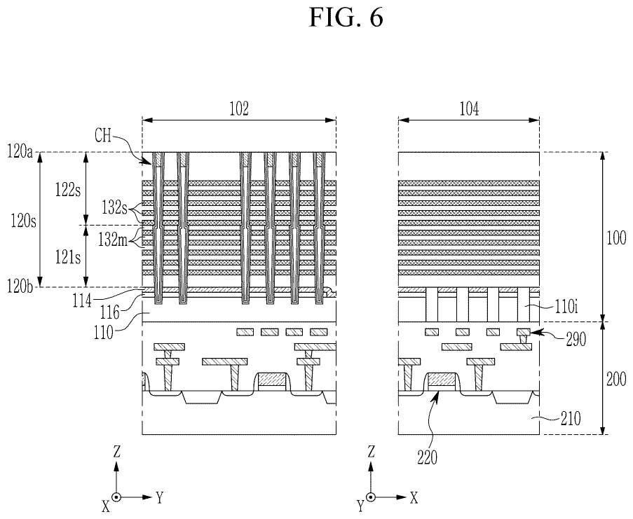

Hereinafter, referring to FIG. 6 to FIG. 16, a manufacturing method of a semiconductor device according to an embodiment will be described in detail. To the extent that an element is not described in detail below, it may be understood that the element is at least similar to a corresponding element that has been described elsewhere within the present disclosure. A portion which is not described in the above will be described in detail.

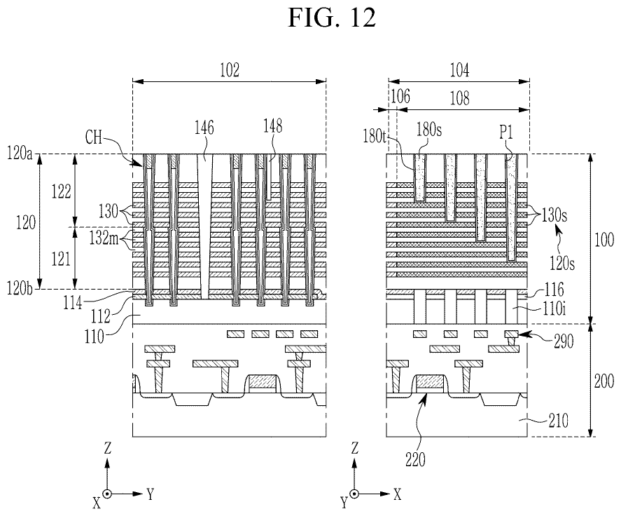

FIG. 6 to FIG. 16 are cross-sectional views illustrating a manufacturing method of a semiconductor device according to an embodiment. FIG. 6 and FIG. 12 illustrate portions corresponding to portions taken along a line A-A′ and a line C-C′ in FIG. 3. FIG. 7 to FIG. 11 and FIG. 13 to FIG. 16 illustrate a portion corresponding to a portion taken along a line C-C′ in FIG. 3. Hereinafter, in a manufacturing method of a semiconductor device, a gate stacking structure 120, a channel structure CH, a separation structure 146, and a gate contact 180 are mainly described.

As illustrated in FIG. 6, a second substrate 110 and an insulation stacking structure 120s may be formed on a circuit region 200, and a channel structure CH extending to pass through the insulation stacking structure 120s may be formed. For example, after a horizontal insulation layer 116 and a second horizontal conductive layer 114 may be formed, the insulation stacking structure 120s may be formed on the horizontal insulation layer 116 and the second horizontal conductive layer 114 on the second substrate 110. The channel structure CH may extend to pass through the insulation stacking structure 120s, the second horizontal conductive layer 114, and the horizontal insulation layer 116.

For example, the second substrate 110 may be formed on the circuit region 200, and the horizontal insulation layer 116, the second horizontal conductive layer 114, and the insulation stacking structure 120s may be formed on the second substrate 110. The insulation stacking structure 120s may be formed by alternately stacking interlayer insulation layers 132m and sacrificial insulation layers 130s.

A portion of the sacrificial insulation layer 130s may be replaced with a gate electrode 130 (refer to FIG. 12) through a subsequent process, and may be formed to include a portion in which the gate electrode 130 will be disposed. At least a portion of the horizontal insulation layer 116 may be replaced with a first horizontal conductive layer 112 (refer to FIG. 12) through a subsequent process, and may be formed to include a portion in which the first horizontal conductive layer 112 will be disposed.

The horizontal insulation layer 116 and/or the sacrificial insulation layer 130s may include or be formed of a material different from a material of the interlayer insulation layer 132m. For example, the interlayer insulation layer 132m may include or be formed of at least one of silicon oxide, silicon nitride, silicon oxynitride, a low dielectric constant material, or the like. The sacrificial insulation layer 130s may include or be formed of at least one of silicon, silicon oxide, silicon carbide, silicon nitride, and silicon oxynitride, and may include or be formed of a material different from a material of the interlayer insulation layer 132m.

Before the insulation stacking structure 120s is formed, a penetration insulation portion 110i passing through the second substrate 110, the second horizontal conductive layer 114, and the horizontal insulation layer 116 may be formed. The penetration insulation portion 110i may be formed in a portion in which a gate contact 180 (refer to FIG. 16) (e.g., a first contact 1810) will be disposed. To form penetration insulation portion 110i, a penetration part may be formed in the potion in which the gate contact 180 (e.g., the first contact 1810) will be disposed, and an insulating material may be filled in the penetration part. However, the embodiments are not limited thereto, and the penetration insulation portion 110i may include any of various materials, and may be formed by any of various processes.

In an embodiment, the insulation stacking structure 120s may include a plurality of insulation stacking portions 121s and 122s sequentially stacked on the second substrate 110, and the channel structure CH may include a plurality of channel portions passing through the plurality of insulation stacking portions 121s and 122s, respectively. However, the embodiments are not limited thereto.

In an embodiment, the insulation stacking structure 120s may be disposed in a cell array region 102 and a connection region 104. In the connection region 104, the insulation stacking structure 120s may be formed to include portions corresponding to a first region 106 (refer to FIG. 12) and a second region 108 (refer to FIG. 12).

A preliminary through part that passes through the insulation stacking structure 120s may be formed in a portion in which the channel structure CH will be formed, and the channel structure CH may be formed in the preliminary through part. The process of forming the preliminary through part may be performed by any of various etching processes (e.g., a dry etching process). A gate dielectric layer 150 (refer to FIG. 2), a channel layer 140 (refer to FIG. 2), and a core insulation layer 142 (refer to FIG. 2) may be sequentially formed, and a channel pad 144 (refer to FIG. 2) may be formed to form a channel structure CH. The process of forming the gate dielectric layer 150, the channel layer 140, the core insulation layer 142, or the channel pad 144 may be performed by any of various processes (e.g., a deposition process or the like). A portion (e.g., a first blocking layer 156a (refer to FIG. 2)) of the gate dielectric layer 150 may not be formed, and may be formed in a subsequent process.

In the process of forming the channel structure CH, a penetration dummy structure DH (refer to FIG. 5) may be formed together. However, the embodiments are not limited thereto.

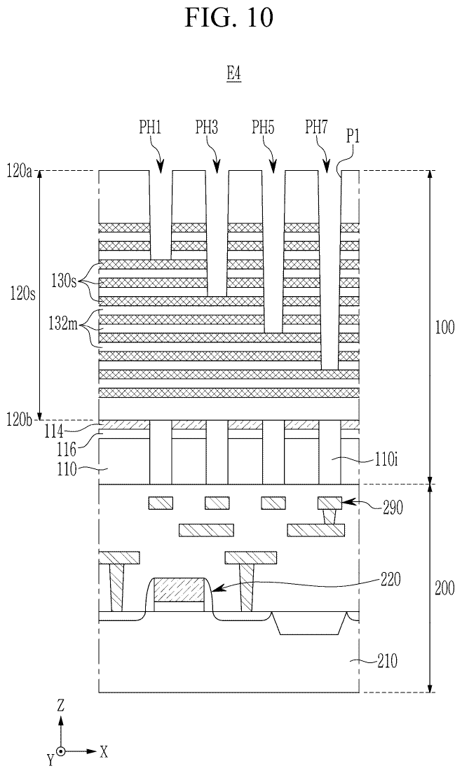

In an embodiment, it is described as an example that a first through portion P1 (refer to FIG. 10) of a through hole is formed after forming the channel structure CH. However, the embodiments are not limited thereto. In some embodiments, before the first through portion P1 is formed, a preliminary through part that passes through the insulation stacking structure 120s may be formed in a portion in which the channel structure CH will be formed, and a channel sacrificial layer may be formed by filling a sacrificial material in the preliminary through part. After the first through portion P1 is formed, the channel sacrificial layer may be removed, and the channel structure CH may be formed.

Subsequently, as illustrated in FIG. 7 to FIG. 10, by performing a first etching process, first through portions P1 of a plurality of through holes PH (refer to FIG. 15) may be formed in portions where first portions 181p of a plurality of gate contacts 180 will be formed. In the first etching process, by using a plurality of partial etching processes (e.g., first to fourth partial etching processes E1, E2, E3, and E4) through binary system, the first through portions P1 of the plurality of through holes PH may be formed.

For a clear understanding and simple illustration, in FIG. 7 to FIG. 10, it is illustrated as an example that a number of sacrificial insulation layers 130s to be replaced to gate electrodes 130 (refer to FIG. 12) is ten (10), and first to fourth partial etching processes E1, E2, E3, and E4 are performed. For a clear understanding, FIG. 7 to FIG. 10 illustrates positions of a first through hole PH1, a third through hole PH3, a fifth through hole PH5, and a seventh through hole PH7 that correspond to a first gate contact, a third gate contact, a fifth gate contact, and a seventh gate contact, respectively. However, the embodiments are not limited thereto, and a number of the sacrificial insulation layers 130s may be variously modified, and a number of partial etching processes may be variously modified according to a number of the sacrificial insulation layers 130s.

In an embodiment, a position (e.g., a position or a level in a vertical direction) of the sacrificial insulation layer 130s to be replaced with the gate electrode 130 may be converted to binary system. According thereto, a plurality of partial etching processes (e.g., first to fourth partial etching processes E1, E2, E3, and E4) may be performed to form a plurality of first through portions P1 of a plurality of through holes PH having different depths. After the first to fourth partial etching processes E1, E2, E3, and E4, an additional partial etching process may be further performed.

The plurality of partial etching processes (e.g., the first to fourth partial etching processes E1, E2, E3, and E4) may be cyclic etching processes. In each partial etching process, a mask configured to expose a predetermined portion may be formed, the partial etching process according to binary system may be performed, and the mask may be removed. In the additional partial etching process, a mask configured to expose a predetermined portion may be formed, an etching process according to binary system or a sequential etching process may be performed, and the mask may be removed. The mask may be a photoresist layer or a hard mask layer including or formed of a photosensitivity material. In the first to fourth partial etching processes E1, E2, E3, and E4 and/or the additional partial etching process, the process of etching the insulation stacking structure 120s may be performed by any of various etching processes (e.g., a dry etching process or the like).

For example, in the plurality of partial etching processes (e.g., the first to fourth partial etching processes E1, E2, E3, and E4) using the binary system, the interlayer insulation layer 132m or the sacrificial insulation layer 130s of 1, 2, 4, . . . , 2⁽ⁿ⁻¹⁾ may be etched according to the binary system.

For example, a position (i.e., 3) of a third sacrificial insulation layer corresponding to a third gate electrode to which a first gate contact is electrically connected may be converted to 11 according to the binary system, and a first through portion P1 of a first through hole PH1 may be formed by performing the first partial etching process E1 and the second partial etching process E2. For example, a position (i.e., 5) of a fifth sacrificial insulation layer corresponding to a fifth gate electrode to which a third gate contact is electrically connected may be converted to 101 according to the binary system, and a first through portion P1 of a third through hole PH3 may be formed by performing the first partial etching process E1 and the third partial etching process E32. For example, a position (i.e., 7) of a seventh sacrificial insulation layer corresponding to a seventh gate electrode to which a fifth gate contact is electrically connected may be converted to 111 according to the binary system, and a first through portion P1 of a fifth through hole PH5 may be formed by performing the first partial etching process E1, the second partial etching process E2, and the third partial etching process E3. For example, a position (i.e., 9) of a ninth sacrificial insulation layer corresponding to a ninth gate electrode to which a seventh gate contact is electrically connected may be converted to 1001 according to the binary system, and a first through portion P1 of a seventh through hole PH7 may be formed by performing the first partial etching process E1 and the fourth partial etching process E4.

Hereinafter, referring to FIG. 7 to FIG. 10, the first through hole PH1, the third through hole PH3, the fifth through hole PH5, and the seventh through hole PH7 may be described in more detail.

As illustrated in FIG. 7, in the first partial etching process E1, portions of a plurality of through holes PH that correspond to the first partial etching process E1 may be selectively etched. For example, in the first partial etching process E1, in portions that correspond to the first through hole PH1, the third through hole PH3, the fifth through hole PH5, and the seventh through hole PH7, one interlayer insulation layer 132m may be etched.

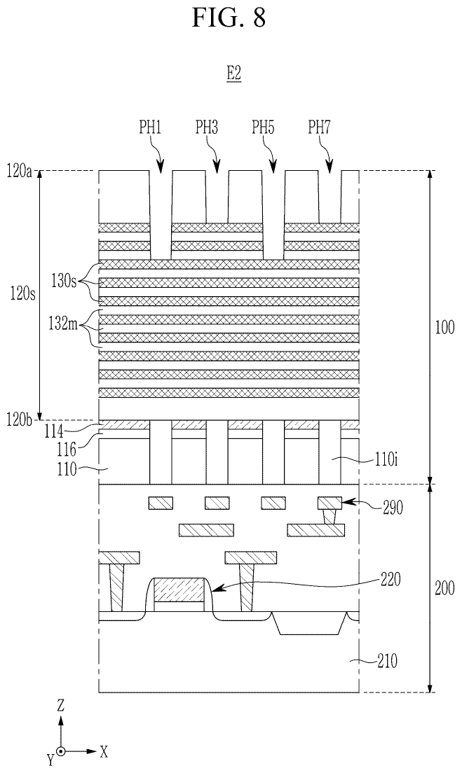

Subsequently, as illustrated in FIG. 8, in the second partial etching process E2, portions of the plurality of through holes PH that correspond to the second partial etching process E2 may be selectively etched. For example, in the second partial etching process E2, in portions that correspond to the first through hole PH1 and the fifth through hole PH5, two interlayer insulation layers 132m and sacrificial insulation layers 130s thereon may be etched.

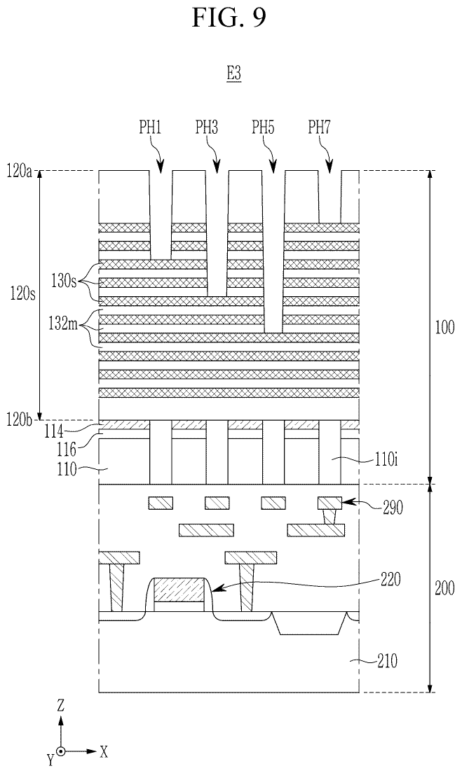

Subsequently, as illustrated in FIG. 9, in the third partial etching process E3, portions of the plurality of through holes PH that correspond to the third partial etching process E3 may be selectively etched. For example, in the third partial etching process E3, in portions that correspond to the third through hole PH3 and the fifth through hole PH5, four sacrificial insulation layers 130s and sacrificial insulation layers 130s thereon may be etched.

Subsequently, as illustrated in FIG. 10, in the fourth partial etching process E4, portions of the plurality of through holes PH that correspond to the fourth partial etching process E4 may be selectively etched. For example, in the fourth partial etching process E4, in a portion that corresponds to the seventh through hole PH7, eight sacrificial insulation layers 130s and sacrificial insulation layers 130s thereon may be etched.

However, the embodiments are not limited to the partial etching processes, and the partial etching processes using the binary system may be variously modified.

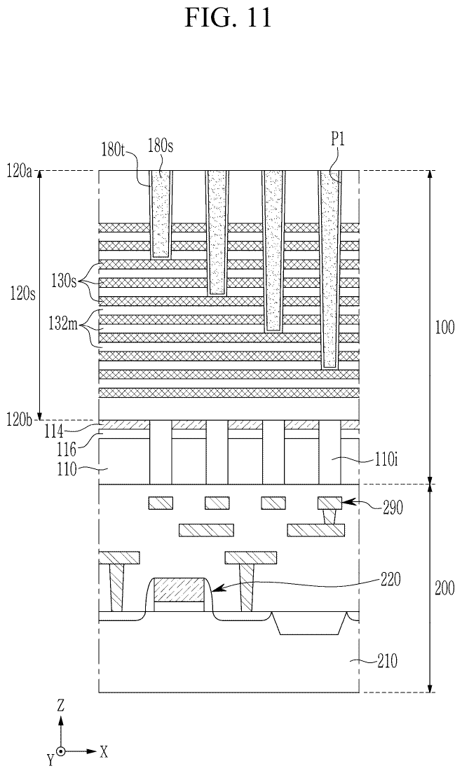

Subsequently, as illustrated in FIG. 11, a protective insulation layer 180t and a penetration sacrificial layer 180s may be formed in each of the plurality of first through portions P1.

The protective insulation layer 180t may be disposed in each of the plurality of first through portions P1. For example, the protective insulation layer 180t may be formed on an inner side surface and a lower surface in each of the plurality of first through portions P1. The process of forming the protective insulation layer 180t may be performed by any of various processes (e.g., a deposition process or the like). However, the embodiments are not limited thereto.

After the protective insulation layer 180t is formed, the penetration sacrificial layer 180s may be formed on the protective insulation layer 180t in the first through portion P1. The penetration sacrificial layer 180s may include or be formed of at least one of polycrystalline silicon, tungsten, titanium nitride, and carbon. However, the embodiments are not limited thereto, and the penetration sacrificial layer 180s may include any of various materials.

Subsequently, as illustrated in FIG. 12, a gate electrode 130 and a separation structure 146 may be formed. The separation structure 146 may include a first separation structure 146a (refer to FIG. 3) and a second separation structure 146b (refer to FIG. 3). In a plan view, the first separation structure 146a and the second separation structure 146b may have different lengths.

An opening for a separation structure that passes through the insulation stacking structure 120s may be formed in an area corresponding to the separation structure 146, the sacrificial insulation layers 130s may be replaced with gate electrodes 130, and the opening for the separation structure may be filled with an insulating material or the like to form the separation structure 146.

In an embodiment, the opening for the separation structure may be formed by an etching process (e.g., a dry etching process or the like). The sacrificial insulation layers 130s may be selectively removed by an etching process (e.g., a wet etching process) through the opening for the separation structure. For example, a portion of the sacrificial insulation layer 130s in the cell array region 102, and the first region 106 of the connection region 104 may be selectively removed. Another portion of the sacrificial insulation layer 130s in the second region 108 of the connection region 104 that is spaced apart from the second separation structure 146b may not be etched and may remain.

The gate electrodes 130 may be formed by filling portions from which the sacrificial insulation layers 130s were removed with a conductive material. As a result, areas where the sacrificial insulation layers 130s were disposed in the cell array region 102 and the first region 106 of the connection region 104 may be replaced with the gate electrodes 130. In this instance, a process of forming a portion of a blocking layer 156 (refer to FIG. 2) (for example, a first blocking layer 156a (refer to FIG. 2)) may be further performed before the process of filing the conductive material constituting the gate electrodes 130. However, the embodiments are not limited thereto.

In some embodiments, the opening for the separation structure may expose the horizontal insulation layer 116. In the etching process through the opening for the separation structure, at least a portion of the horizontal insulation layer 116 and at least a portion of the gate dielectric layer 150 may be removed, and a material of a first horizontal conductive layer 112 may be filled. Thereby, the first horizontal conductive layer 112 may be formed.

The separation structure 146 may be formed by filling the opening for the separation structure. The process of filling the opening for the separation structure may be performed by any of various processes (e.g., a deposition process or the like). In an embodiment, the first region 106 may be disposed adjacent to the first separation structure 146a, and the second region 108 may be spaced apart from the second separation structure 146b between two adjacent first separation structures 146a.

In some embodiments, an upper separation region 148 may be formed in a portion of the gate stacking structure 120. The upper separation region 148 may be formed by forming an opening for a separation pattern through an etching process using a mask layer and filling an insulating material to at least a portion of the opening for the separation pattern. The process of forming the opening for the separation pattern may be performed by any of various etching processes (e.g., a dry etching process). In the process forming the insulating material in the opening for the separation pattern may be performed by any of various processes (e.g., a deposition process or the like). An order of the process of forming the opening for the separation pattern and the process forming the insulating material in the opening for the separation pattern may be variously modified.

In an embodiment, it is described as an example that the opening for the separation structure is formed after the first through portion P1, the protective insulation layer 180t, and the penetration sacrificial layer 180s are formed. However, the embodiments are not limited thereto. Before the first through portion P1 is formed, the opening for the separation structure may be formed, and a sacrificial layer may be formed in the opening for the separation structure. In this instance, after the sacrificial layer in the opening for the separation structure is removed, the replacement process with the gate electrode 130, the replacement process with the first horizontal conductive layer 112, or the like may be performed.

Subsequently, as illustrated in FIG. 13, a lower portion of the protective insulation layer 180t (refer to FIG. 12) on a lower surface of the first through portion P1 (i.e., a portion of the protective insulation layer 180t on an upper surface of the gate electrode 130) may be removed to form a side insulation layer 180b. The lower portion of the protective insulation layer 180t may be removed by any of various processes (e.g., an etching process, as an example, a dry etching process).

Subsequently, as illustrated in FIG. 14, a connection through portion PC corresponding to a connection part 180c (refer to FIG. 16) may be formed. For example, by performing a wet etching process through the first through portion P1, a portion of the sacrificial insulation layer 130s where the first through portion P1 reaches may be removed. By the wet etching process, a portion of the sacrificial insulation layer 130s may be etched in a horizontal direction, and the connection through portion PC having an area greater than an area of the first through portion P1 may be formed. For example, when viewed in cross-section, the connection through portion PC may be formed to have a horizontal width that is greater than a horizontal width of the first through portion P1. Thereby, the connection through portion PC may be formed by an easy process.

Subsequently, as illustrated in FIG. 15, by performing a second etching process, a plurality of second through portions P2 of the through holes PH may be formed in portions where second portions 182p (refer to FIG. 16) of the plurality of gate contacts 180 will be disposed. In the second etching process, the second through portion P2 may be formed. The second through portion P2 may extend from a second surface (a lower surface in FIG. 15) of the connection through portion PC to a second surface 120b (a lower surface in FIG. 15) of the insulation stacking structure 120s in a thickness direction of a semiconductor device (a Z-axis direction in the drawings).

In the second etching process, using a mask having an opening configured to expose a predetermined portion, the predetermined portion may be selectively etched. The mask may be a photoresist layer or a hard mask layer including or formed of a photosensitivity material. In the second etching process, the insulation stacking structure 120s may be selectively etched by any of various etching processes (e.g., a dry etching process). After the insulation stacking structure 120s is selectively etched, the mask may be removed.

In some embodiments, in the second etching process, the second through portion P2 may extend from the second surface of the connection through portion PC and may pass through the second surface 120b of the insulation stacking structure 120s, the penetration insulation portion 110i, and an insulation layer of the circuit region 200. Accordingly, the second through portion P2 may connect the second surface of the connection through portion PC and a wiring layer of the circuit wiring portion 290. However, the embodiments are not limited thereto. In some embodiments, the second through portion P2 may not pass through the second surface 120b of the insulation stacking structure 120s, the penetration insulation portion 110i, and/or the insulation layer of the circuit region 200.

Subsequently, as illustrated in FIG. 16, a conductive portion 180a may be formed by filling the through hole PH with a conductive material. Thereby, a gate contact 180 may be formed.

Subsequently, a cell wiring portion 190 (refer to FIG. 1) including a bit line 192 (refer to FIG. 1) connected to the channel structure CH or the like may be formed. Thereby, a semiconductor device illustrated in FIG. 1 may be formed.

According to embodiment, by using the first etching process including the partial etching processes according to the binary system, the first through portion P1 of the through hole PH in which the first portion 181p of the gate contact 180 is disposed may be formed. Accordingly, the process of forming the gate contact 180 may be simplified, and an area of the connection region 104 may be reduced.

The gate contact 180 may be disposed in the insulation stacking structure 120s, and the first through portion P1 of the through hole PH may be stably formed. For example, if a process error may be undesirably induced in the process of forming the first through portion P1 of the through hole PH, the gate contact 180 may be disposed in the insulation stacking structure 120s and thus an unwanted electrical short circuit may be prevented or minimized. The gate contact 180 may be disposed in a space separated from the penetration dummy structure DH, and the gate contact 180 may be stably formed.

Thereby, the semiconductor device may be stably formed by an easy manufacturing process.

In the above description, it is described as an example that the process of forming the opening for the separation structure, the process of replacing the portion of the sacrificial insulation layer 130s with the gate electrode 130, and the process of forming the separation structure 146 are performed after the first through portion P1 is formed. However, the embodiments are not limited thereto. In some embodiments, the first through portion P1 may be formed after the process of forming the opening for the separation structure, the process of replacing the portion of the sacrificial insulation layer 130s with the gate electrode 130, and the process of forming the separation structure 146 are performed. Thereby, a number of processes may be reduced. For example, the process of forming the penetration sacrificial layer 180s may be omitted. Other various modified embodiments are possible.

Hereinafter, referring to FIG. 17 to FIG. 36, semiconductor devices and manufacturing methods thereof according to embodiments will be described in more detail. To the extent that an element is not described in detail below, it may be understood that the element is at least similar to a corresponding element that has been described elsewhere within the present disclosure. A portion which is not described in the above will be described in detail.

FIG. 17 is a cross-sectional view illustrating a semiconductor device according to an embodiment. FIG. 17 illustrates a portion corresponding to a portion in FIG. 1.

Referring to FIG. 17, in an embodiment, a gate contact 180 may include a first contact 1810 and a second contact 1820.

A description of a first contact 1810 described with reference to FIG. 1 to FIG. 16 may be applied to the first contact 1810. The second contact 1820 may have a structure or a shape different from a structure or a shape of the first contact 1810.

In the second contact 1820, a penetration part 180p may include or be formed of a portion corresponding to a first portion 181p of the first contact 1810 that is disposed on a first surface (an upper surface in FIG. 17) of a connection part 180c. The penetration part 180p may not include a portion corresponding to a second portion 182p of the first contact 1810 that is disposed on a second surface (a lower surface in FIG. 17) of the connection part 180c opposite to the first surface of the connection part 180c. That is, the penetration part 180p may be disposed on the first surface of the connection part 180c, and may not be disposed on the second surface of the connection part 180c opposite to the first surface of the connection part 180c. Accordingly, the connection part 180c may be disposed in an end portion of the penetration part 180p. In the second contact 1820, a side insulation layer 180b may be disposed in the entirety of a side surface of the penetration part 180p, and the side insulation layer 180b may not include a portion corresponding to the second portion 182p of the first contact 1810 in which the side insulation layer 180b is not disposed.

In an embodiment, the second contact 1820 may be electrically connected to a first wiring portion (e.g., a cell wiring portion 190) on a first surface 120a of a stacking structure (e.g., an insulation stacking structure 120s) through the penetration part 180p. The second contact 1820 (e.g., the penetration part 180p and the connection part 180c) may be spaced apart from a second surface 120b of the stacking structure (e.g., the insulation stacking structure 120s) and/or a second wiring portion (e.g., a circuit wiring portion 290), and may be electrically insulated from the second wiring portion. That is, the second contact 1820 may be a second connection contact. The second connection contact may be electrically connected to one of the first wiring portion and the second wiring portion, and may not be electrically connected to the other one of the first wiring portion and the second wiring portion

For example, a process of forming the second contact 1820 may include a first etching process (refer to FIG. 7 to FIG. 10), a process of forming a side insulation layer 180b (refer to FIG. 13), a process of forming a connection through portion of a through hole PH (refer to FIG. 14), and a process of forming a conductive portion 180a (refer to FIG. 16). In the first etching process, a first through portion of the through hole PH may be formed in a portion where the penetration part 180p will be formed. In the process of forming the side insulation layer 180b, the side insulation layer 180b may be formed on a side surface of the first through portion of the through hole PH. In the process of forming the connection through portion of the through hole PH, the connection through portion of the through hole PH may be formed in a portion in which the connection part 180c will be disposed. The first etching process may include a plurality of partial etching processes using the binary system.

That is, the second contact 1820 may be formed without a second etching process of forming a second through portion (refer to FIG. 15) of the through hole PH in a portion in which the second portion 182p will be disposed.

In FIG. 17, it is illustrated as an example that the gate contact 180 having the connection part 180c at a first position, which is relatively highly disposed (e.g., at a relatively higher vertical level), is the second contact 1820, and the gate contact 180 having the connection part 180c at a second position, which is relatively lowly disposed (e.g., at a relatively lower vertical level), is the first contact 1810. Thereby, in the second etching process configured to form the second portion 182p of the first contact 1810, a number of an etched layer may be reduced. The second etching process may be easily performed and time of the second etching process may be reduced. However, the embodiments are not limited thereto, and an arrangement of the first contact 1810 or the second contact 1820 or a position of the connection part 180c in the first contact 1810 or the second contact 1820 may be variously modified.

In an embodiment, the plurality of gate contacts 180 may include the first contact 1810 and the second contact 1820, and a process of forming the plurality of gate contacts 180 may be easily performed and time of the process of forming the plurality of gate contacts 180 may be reduced, and a freedom of a wiring may be improved.

FIG. 18 is a cross-sectional view illustrating a semiconductor device according to an embodiment. FIG. 18 illustrates a portion corresponding to FIG. 5.

Referring to FIG. 18, in an embodiment, a first contact 1810 may be an expanded contact. The expanded contact may further include an expanded portion 180e that extends horizontally from a second portion 182p and is spaced apart from and electrically insulated from a gate electrode 130 of a gate stacking structure 120. An area (e.g., a planar area) of the expanded portion 180e may be less than an area (e.g., a planar area) of the connection part 180c, and the expanded portion 180e may be spaced apart from and electrically insulated from the gate electrode 130 of the gate stacking structure 120. For example, when viewed in cross-section, a horizontal width of the expanded portion 180e may be less than a horizontal width of the connection part 180c.

In some embodiments, the expanded portion 180e may be configured to relieve a stress applied to a semiconductor device and reduce a warpage, a crack, or the like of the semiconductor device. For example, a process of forming the first contact 1810 may include a second etching process, and an etching process of forming an expanded through portion in which the expanded portion 180e will be disposed after the second etching process.

In some embodiments, in a process of forming a first through portion of a through hole in which a first portion 181p of the first contact 1810 will be disposed, another sacrificial insulation layer 130s (e.g., a lower sacrificial insulation layer) below a sacrificial insulation layer 130s in which the connection part 180c will be disposed may be etched undesirably by a process error. For example, a pin-hole may be formed. Therefore, in a process of forming a connection through portion, a portion of the lower sacrificial insulation layer may be etched undesirably and an expanded through portion may be formed. In this instance, the expanded through portion in the lower sacrificial insulation layer may have an area less than an area of the connection through portion. Thereby, when the conductive portion 180a is formed, the expanded portion 180e may have an area less than an area of the connection part 180c. Accordingly, the expanded portion 180e may be spaced apart from the gate electrode 130 disposed in a first region 106. Therefore, if the process error, the pin-hole, or the like may be induced, an unwanted electrical short circuit may be prevented and a process margin may be sufficient.

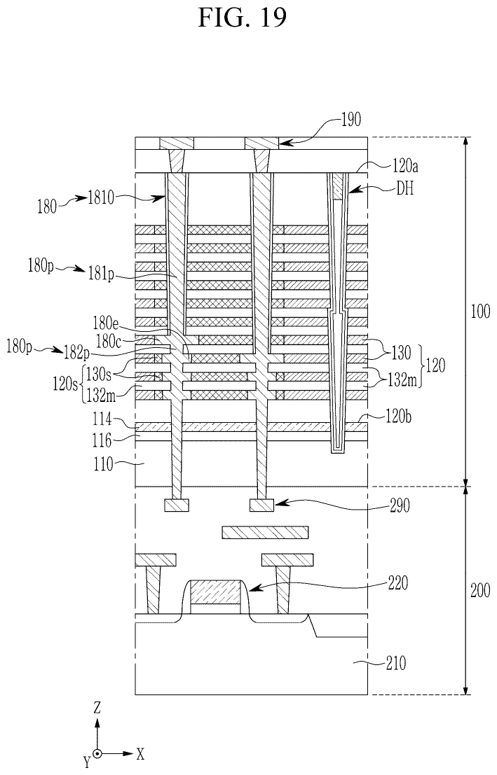

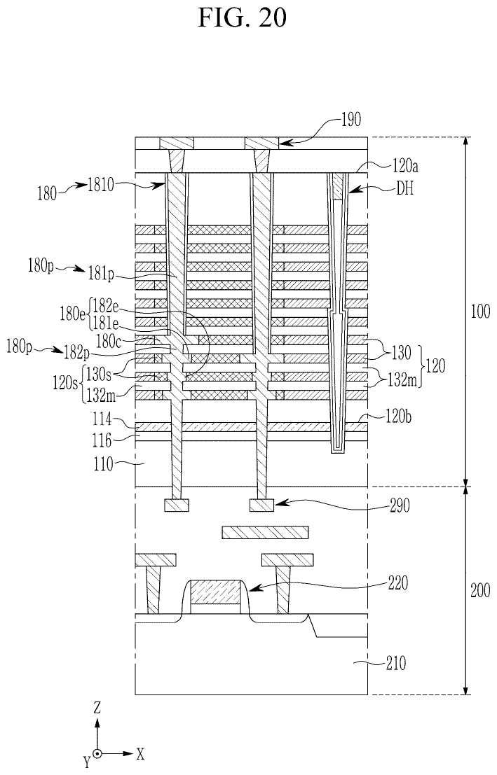

In FIG. 18, it is illustrated as an example that one expanded portion 180e is disposed in the end portion of the penetration part 180p, the second portion 182p of the penetration part 180p connects the connection part 180c and the expanded portion 180e, and the first contact 1810 is electrically insulated form a second wiring portion (e.g., a circuit wiring portion 290). That is, the first contact 1810 including the expanded portion 180e may be a second connection contact. The second connection contact may be electrically connected to one of a first wiring portion and a second wiring portion, and may not be electrically connected to the other one of the first wiring portion and the second wiring portion. In this instance, the process of forming the first contact 1810 may not include the second etching process. However, the embodiments are not limited thereto. An embodiment will be described later in detail with reference to FIG. 19 and FIG. 20.

In FIG. 18, it is illustrated as an example that the first contact 1810 of the expanded contact and the second contact 1820 are included together, but the embodiments are not limited thereto. A first contact 1810 of a base contact may be further included, or the second contact 1820 may be omitted.

In some embodiments, by the expanded portion 180e, the stress applied to the semiconductor device may be relieved and a warpage, a crack, or the like of the semiconductor device may be reduced. In some embodiments, when there is the process error or the like, the expanded portion 180e having the area less than the area of the connection part 180c may be formed, and a process margin may be sufficient.

FIG. 19 is a cross-sectional view illustrating a semiconductor device according to an embodiment. FIG. 19 illustrates a portion corresponding to FIG. 5.

Referring to FIG. 19, in an embodiment, a first contact 1810 may be an expanded contact. The expanded contact may further include an expanded portion 180e that extends horizontally from a second portion 182p and is spaced apart from and electrically insulated from a gate electrode 130 of a gate stacking structure 120. In an embodiment, by the expanded portion 180e, a stress applied to a semiconductor device may be relieved and a warpage, a crack, or the like of the semiconductor device may be reduced.

In an embodiment, the second portion 182p may passes through the expanded portion 180e. The second portion 182p may include a portion that is disposed on a first surface of the expanded portion 180e, and a portion that is disposed on a second surface of the expanded portion 180e opposite to the first surface of the expanded portion 180e.

For example, the first contact 1810 may be electrically connected to a first wiring portion (e.g., a cell wiring portion 190) on a first surface 120a of a stacking structure (e.g., an insulation stacking structure 120s) through a first portion 181p, and may be electrically connected to a second wiring portion (e.g., a circuit wiring portion 290) on a second surface 120b of the stacking structure (e.g., the insulation stacking structure 120s) through a second portion 182p. That is, the first contact 1810 may be a first connection contact that is electrically connected to the first wiring portion and the second wiring portion on opposite sides of the stacking structure.

In some embodiments, the expanded portion 180e may include a plurality of expanded portions 180e having a same area, and may be formed by an easy manufacturing process.

In some embodiments, as illustrated in FIG. 20, an expanded portion 180e may include a plurality of expanded portions 180e having different areas. For example, the expanded portion 180e may include a first expanded portion 181e, and a second expanded portion 182e having an area less than an area of the first expanded portion 181e. For example, when viewed in cross-section, the first expanded portion 181e may have a horizontal width greater than a horizontal width of the second expanded portion 182e. By any of various methods, an area of the first expanded portion 181e and an area of the second expanded portion 182e may be different. For example, by a difference in composition of sacrificial insulation layers 130s, the area of the first expanded portion 181e and the area of the second expanded portion 182e may be adjusted. The sacrificial insulation layer 130s may include a first sacrificial insulation layer and a second sacrificial insulation layer. The first sacrificial insulation layer may be disposed in a layer corresponding to the first expanded portion 181e. The second sacrificial insulation layer may be disposed in a layer corresponding to the second expanded portion 182e, and may have a composition different from a composition of the first sacrificial insulation layer. For example, when the sacrificial insulation layer 130s includes silicon nitride, the first sacrificial insulation layer may have a silicon amount less than a silicon amount of the second sacrificial insulation layer, the first sacrificial insulation layer may have a nitrogen amount greater than a nitrogen amount of the second sacrificial insulation layer, and/or the first sacrificial insulation layer may have a hydrogen amount greater than a hydrogen amount of the second sacrificial insulation layer.

In some embodiments, areas of the plurality of expanded portions 180e may decrease in stages as the plurality of expanded portions 180e go downward, or areas of the plurality of expanded portions 180e may increase in stages as the plurality of expanded portions 180e go downward. Other various modified embodiments are possible.

In an embodiment, the gate contact 180 may include a first contact 1810 (e.g., a base contact, an expanded contact, a first connection contact, or a second connection contact) described with reference to FIG. 1 to FIG. 20, and further include a second contact. Further, a contact having a structure or a shape different from a structure or a shape of the first contact, the second contact, the base contact, the expanded contact, the first connection contact, or the second connection contact may be further included.

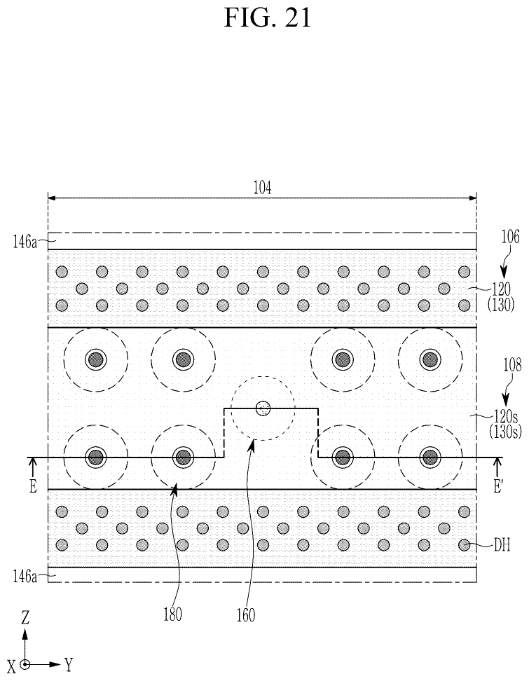

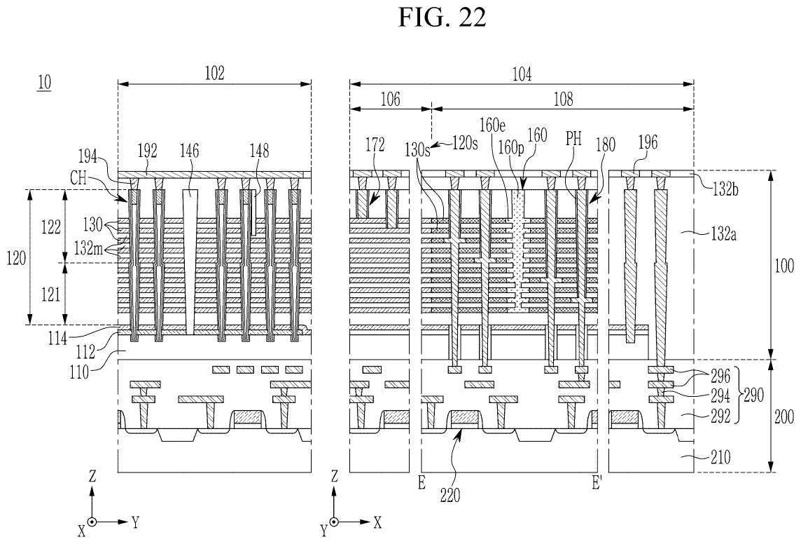

FIG. 21 is a plan view schematically illustrating a semiconductor device according to an embodiment. FIG. 22 is a cross-sectional view of the semiconductor device illustrated in FIG. 21. FIG. 21 illustrates a portion corresponding to FIG. 4, and FIG. 22 illustrates a portion corresponding to FIG. 1. In FIG. 22, a connection region 104 includes a portion taken along a line E-E′ in FIG. 21.

Referring to FIG. 21 and FIG. 22, in an embodiment, in a second region 108 of a connection region 104, an expanded dummy structure 160 that has a structure or a shape same as or similar to a structure or a shape of a gate contact 180.

The expanded dummy structure 160 may include a dummy penetration part 160p that passes through an insulation stacking structure 120s, and a dummy expanded portion 160e that extends horizontally to have an area greater than an area of the dummy penetration part 160p. For example, when viewed in cross-section, a horizontal width of the dummy expanded portion 160e may be greater than a horizontal width of the dummy penetration part 160p.

The dummy penetration part 160p may extend to pass through the insulation stacking structure 120s in a thickness direction of a semiconductor device (a Z-axis direction in the drawings), and the dummy expanded portion 160e may extend horizontally to have an area (e.g., a planar area) greater than an area of the dummy penetration part 160p. For example, when viewed in cross-section, the dummy expanded portion 160e may have a horizontal width that is greater than a horizontal width of the dummy penetration part 160p. For example, a plurality of dummy expanded portions 160e may be provided to one-to-one correspond to a plurality of sacrificial insulation layers 130s.

By the expanded dummy structure 160, a stress applied to a semiconductor device may be relieved and a warpage, a crack, or the like of the semiconductor device may be reduced. For example, in the semiconductor device, the stress may be applied to the semiconductor device by an area of the gate stacking structure 120 and an area of the insulation stacking structure 120s. The expanded dummy structure 160 may include a material capable of relieving the stress applied to the semiconductor device, and/or the expanded dummy structure 160 may be disposed at a position capable of relieving the stress applied to the semiconductor device. The expanded dummy structure 160 may include the dummy penetration part 160p passing through the insulation stacking structure 120s and the dummy expanded portion 160e expanded therefrom, and may have a sufficient volume. Accordingly, the stress applied to the semiconductor device may be effectively relieved.

The expanded dummy structure 160 may include or be formed of at least one of an insulating material and a conductive material. In some embodiments, the expanded dummy structure 160 may be disposed in the insulation stacking structure 120s, and the expanded dummy structure 160 may include a conductive material (e.g., metal). The conductive material (e.g., the metal) may effectively relieve the stress applied to the semiconductor device. That is, since the expanded dummy structure 160 may be disposed in a second region 108 in which the insulation stacking structure 120s is disposed, the expanded dummy structure 160 may include the conductive material (e.g., the metal) capable of effectively relieving the stress applied to the semiconductor device. However, the embodiments are not limited thereto, and the expanded dummy structure 160 may include an insulating material.

The expanded dummy structure 160 may include or be formed of a warpage-inducing material that induces a warpage capable of reducing the warpage of the semiconductor device. For example, the warpage-inducing material may induce a warpage in a direction that is opposite to a direction of the warpage of the semiconductor device. The expanded dummy structure 160 may include a compressive-stress material or a tensile-stress material. The compressive-stress material may have a stress of a negative number at a room temperature and apply a compressive stress when the compressive-stress material is disposed on a substrate. The tensile-stress material may have a stress of a positive number at a room temperature and apply a tensile stress when the tensile-stress material is disposed on a substrate.

For example, the expanded dummy structure 160 may include or be formed of at least one of oxide, nitride, carbonitride, oxycarbide, oxynitride, oxycarbonitride, a resin, and metal. For example, the expanded dummy structure 160 may include or be formed of at least one of silicon oxide, aluminum oxide, hafnium oxide, silicon nitride, silicon carbonitride (SiCN), silicon oxycarbide (SiOC), silicon oxynitride (SiON), silicon oxycarbonitride (SiOCN), a resin, tungsten (W), copper (Cu), and aluminum (Al).

Silicon oxide, aluminum oxide, or hafnium oxide may be the compressive-stress material. Silicon nitride, silicon carbonitride, or metal (e.g., tungsten (W), copper (Cu), aluminum (Al)) may be the tensile-stress material. Silicon oxycarbide, silicon oxynitride, or silicon oxycarbonitride may be the compressive-stress material or the tensile-stress material according to a composition. The resin may be generally the tensile-stress material, but the resin may be the compressive-stress material according to a material or a composition.

The compressive stress or the tensile stress of the expanded dummy structure 160 may be adjusted by adjusting a composition, a manufacturing process, a process condition, or the like of the expanded dummy structure 160.

In an embodiment, the expanded dummy structure 160 may be formed using at least a part of a process of forming the gate contact 180.

For example, in a first etching process (refer to FIG. 7 to FIG. 10) and/or a second etching process (refer to FIG. 15), a through portion corresponding to the dummy penetration part 160p may be formed. In the first etching process, a first through portion of a through hole PH in which at least a portion of a penetration part 180p of the gate contact 180 will be disposed may be formed. In the second etching process, a second through portion of the through hole PH in which at least a portion of the penetration part 180p of the gate contact 180 will be disposed may be formed. In a process of forming a connection through portion of the through hole PH (refer to FIG. 14) and a process of forming an expanded through portion corresponding to an expanded portion 180e (refer to FIG. 18 to FIG. 20) of the gate contact 180, a dummy through portion in which the dummy expanded portion 160e of the expanded dummy structure 160 will be disposed may be formed.

For example, when the expanded dummy structure 160 includes the conductive material, in a process of forming a conductive portion 180a (refer to FIG. 16), the expanded dummy structure 160 may be formed by filling the conductive material in the through portion and the dummy through portion corresponding to the expanded dummy structure 160. When the expanded dummy structure 160 include a material other than the conductive material, the expanded dummy structure 160 may be formed by filling the material other than the conductive material in the through portion and the dummy through portion corresponding to the expanded dummy structure 160.

However, the embodiments are not limited thereto, and the expanded dummy structure 160 may be formed by a process separately performed from a process of forming the gate contact 180.

For a clear understanding and simple illustration, in FIG. 21, it is illustrated as an example that one expanded dummy structure 160 is disposed in a central portion of the second region 108 between the plurality of gate contacts 180 in a second direction (a Y-axis direction in the drawings). However, the embodiments are not limited thereto, and a position, an arrangement, a number, or the like of the expanded dummy structure 160 may be variously modified.

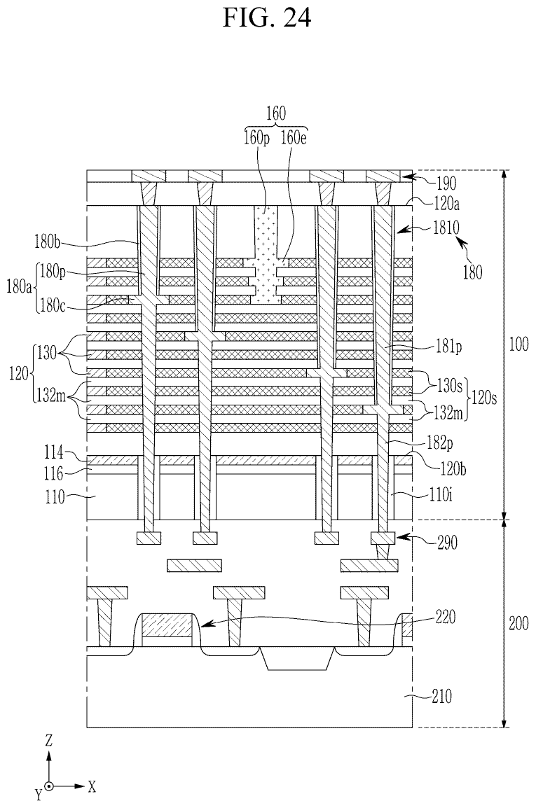

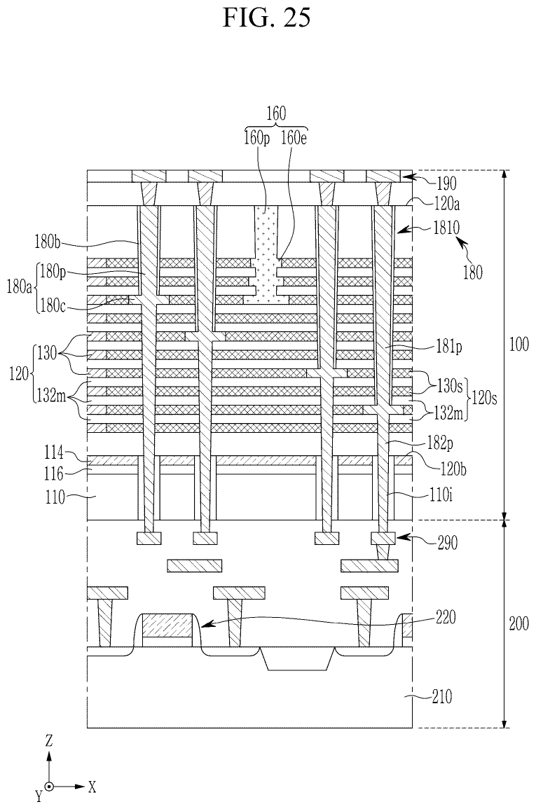

In FIG. 22, it is illustrated as an example that, in the expanded dummy structure 160, the dummy penetration part 160p passes through the entirety of the plurality of sacrificial insulation layers 130s included in the insulation stacking structure 120s, and the plurality of dummy expanded portions 160e corresponds to the plurality of sacrificial insulation layers 130s, respectively. Thereby, the expanded dummy structure 160 may pass through the entirety of the insulation stacking structure 120s, and the expanded dummy structure 160 may effectively relieve the stress applied to the semiconductor device. However, the embodiments are not limited thereto, and, as illustrated FIG. 24 and in FIG. 25, an expanded dummy structure 160 may be disposed in a part of a plurality of sacrificial insulation layers 130s included in an insulation stacking structure 120s.

In an embodiment, by the expanded dummy structure 160, the stress applied to the semiconductor device may be relieved and the warpage, the crack, or the like of the semiconductor device may be reduced.

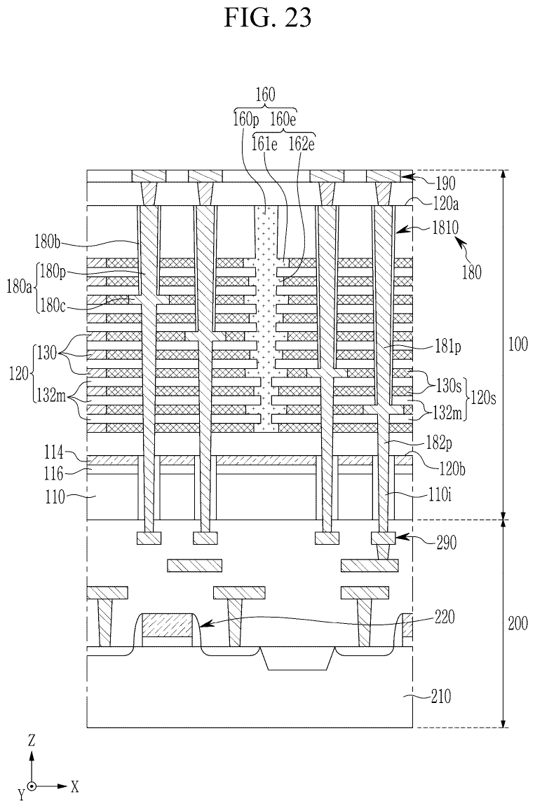

In FIG. 22, it is illustrated as an example that the dummy expanded portion 160e includes a plurality of dummy expanded portions 160e having a same area. However, the embodiments are not limited thereto. As illustrated in FIG. 23 to FIG. 25, the dummy expanded portion 160e may include a plurality of dummy expanded portions 160e having different areas.

For example, as illustrated in FIG. 23, the dummy expanded portion 160e may include a first dummy expanded portion 161e, and a second dummy expanded portion 162e having an area (e.g., a planar area) less than an area of the first dummy expanded portion 161e. For example, when viewed in cross-section, a horizontal width of the first dummy expanded portion 161e may be greater than a horizontal width of the second dummy expanded portion 162e. By any of various methods, an area of the first dummy expanded portion 161e and an area of the second dummy expanded portion 162e may be different from each other. For example, by a difference in composition of sacrificial insulation layers 130s, the area of the first dummy expanded portion 161e and the area of the second dummy expanded portion 162e may be adjusted. The sacrificial insulation layer 130s may include a first sacrificial insulation layer and a second sacrificial insulation layer. The first sacrificial insulation layer may be disposed in a layer corresponding to the first dummy expanded portion 161e. The second sacrificial insulation layer may be disposed in a layer corresponding to the second dummy expanded portion 162e, and may have a composition different from a composition of the first sacrificial insulation layer. For example, when the sacrificial insulation layer 130s include silicon nitride, the first sacrificial insulation layer may have a silicon amount less than a silicon amount of the second sacrificial insulation layer, the first sacrificial insulation layer may have a nitrogen amount greater than a nitrogen amount of the second sacrificial insulation layer, and/or the first sacrificial insulation layer may have a hydrogen amount greater than a hydrogen amount of the second sacrificial insulation layer.

In some embodiments, as illustrated in FIG. 24, areas of the plurality of dummy expanded portions 160e may decrease in stages as the plurality of expanded portions 180e go downward. In some embodiments, as illustrated in FIG. 25, areas of the plurality of dummy expanded portions 160e may increase in stages as the plurality of expanded portions 180e go downward. Other various modified embodiments are possible.

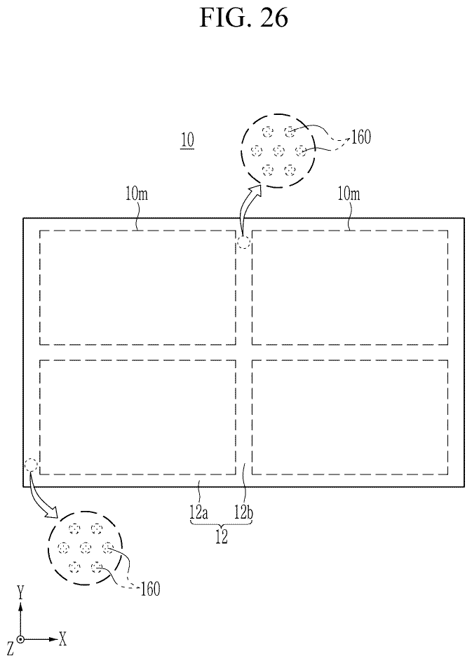

FIG. 26 is a plan view schematically illustrating a semiconductor device 10 according to an embodiment.

Referring to FIG. 26, in an embodiment, a semiconductor device 10 may include a plurality of memory regions 10m that are partitioned, separated, divided, or defined by an outer region 12.

The memory region 10m may be a unit region of the semiconductor device 10. In FIG. 1, it is illustrated as an example that the semiconductor device 10 includes a plurality of memory regions 10m adjacent to each other in a first direction (an X-axis direction in the drawings), and includes a plurality of memory regions 10m adjacent to each other in a second direction (a Y-axis direction in the drawings). However, the embodiments are not limited thereto. A number, an arrangement, or the like of the plurality of memory regions 10m may be variously modified.

The outer region 12 may be disposed outside the plurality of memory regions 10m and may partition, separate, divide, or define the plurality of memory regions 10m. The outer region 12 may include at least one first outer region 12a and at least one second outer region 12b. The first outer region 12a may extend longitudinally in the first direction (the X-axis direction in the drawings). The second outer region 12b may extend longitudinally in the second direction (the Y-axis direction in the drawings). Thereby, a structure of the outer region 12 may be simplified. However, the embodiments are not limited thereto. In some embodiments, the first and/or second outer region 12a and/or 12b may include a bent portion, a folded portion, a curved portion, a rounded portion, or the like according to an arrangement of the plurality of memory regions 10m.

The outer region 12 may include portion between the plurality of memory regions 10m and a portion between the plurality of memory regions 10m and an edge of the semiconductor device 10. At least a portion of the outer region 12 may be a cut region, a scribing lane, or the like.

In an embodiment, in the outer region 12 of the semiconductor device 10, an expanded dummy structure 160 may be disposed. For example, the expanded dummy structure 160 may be disposed in any of various positions. For example, in a plan view, the expanded dummy structure 160 may be disposed in the portion between the plurality of memory regions 10m and/or in the portion between the memory region 10m and the edge of the semiconductor device 10. However, the embodiments are not limited thereto. Accordingly, a position, a shape, an arrangement, a number, or the like of the expanded dummy structure 160 may be variously modified. For example, the expanded dummy structure 160 may be disposed in a portion of the memory region 10m.

In the outer region 12 in which the expanded dummy structure 160 is disposed, an insulation stacking structure may be disposed, or an insulation structure formed after the insulation stacking structure is removed may be disposed.

In FIG. 26, it is illustrated as an example that the expanded dummy structures 160 are disposed to have a honeycomb structure. Thereby, the expanded dummy structures 160 may be provided to have a high density. However, the embodiments are not limited thereto, and the expanded dummy structure 160 may have any of various arrangements.

In an embodiment, in FIG. 21 to FIG. 26, it is illustrated as an example that the expanded dummy structure 160 is disposed in the second region 108 or the outer region 12. However, the embodiments are not limited thereto, and the expanded dummy structure 160 may be disposed in any of various positions in a portion other than the cell array region 102 or in a portion in which the insulation stacking structure is disposed.

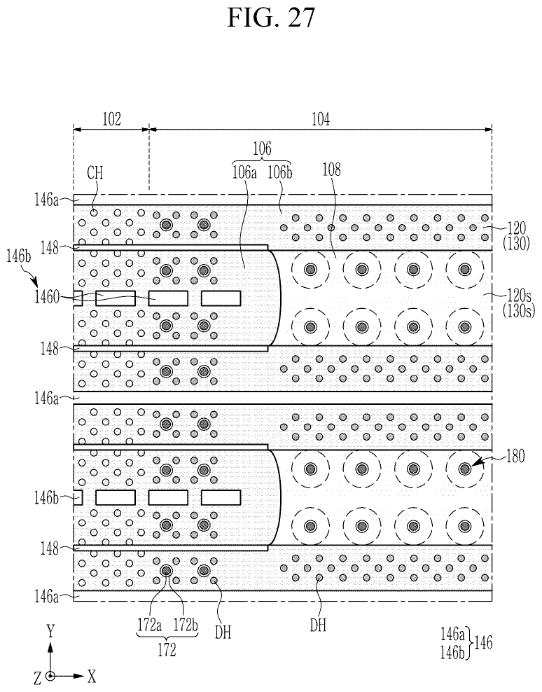

FIG. 27 is a plan view schematically illustrating a semiconductor device according to an embodiment. FIG. 27 illustrates a portion corresponding to FIG. 3.

Referring to FIG. 27, in an embodiment, a second separation structure 146b may include a plurality of separation portions 1460 that extend in a first direction and are spaced apart from each other in the first direction. When the second separation structure 146b includes the plurality of separation portions 1460, a sacrificial insulation layer 130s may be stably replaced with a gate electrode 130 in a first region 106. By the plurality of separation portions 1460, the gate stacking structure 120 may have a relatively large area, and a structural stability in the process of replacing the sacrificial insulation layer 130s to the gate electrode 130 may be improved.

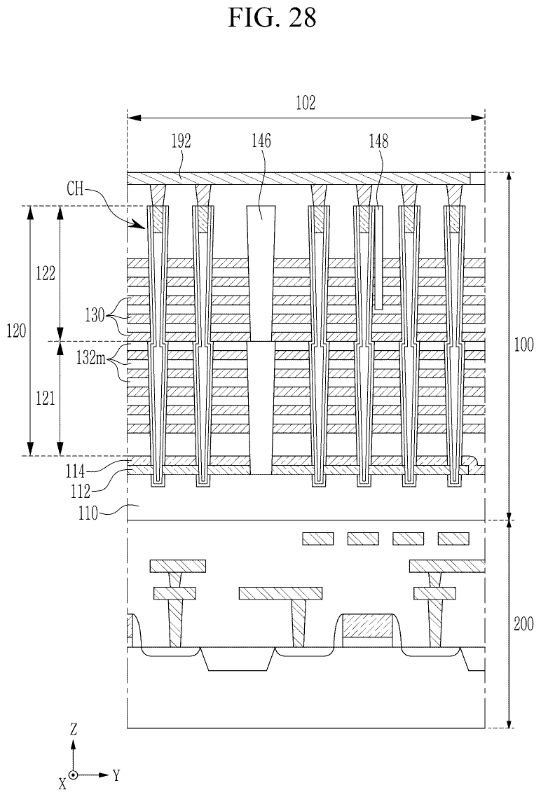

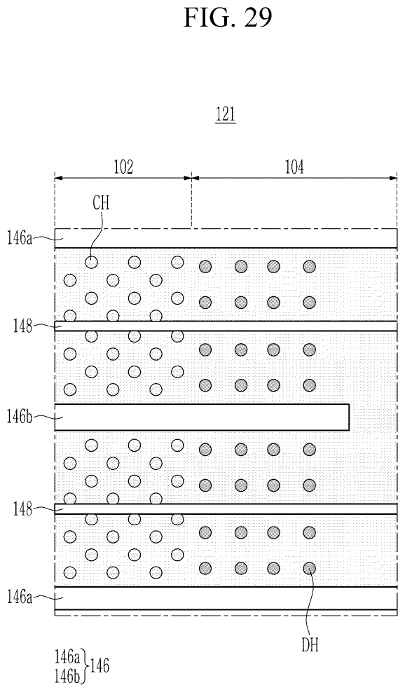

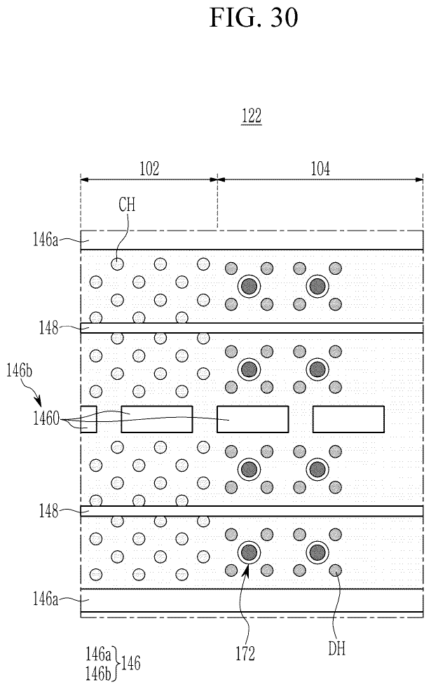

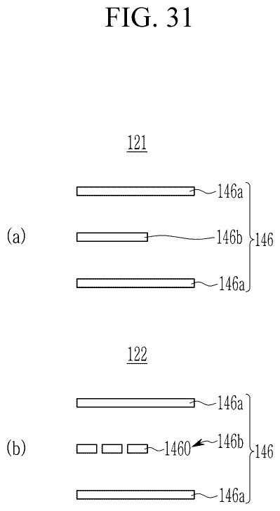

FIG. 28 is a cross-sectional view schematically illustrating a semiconductor device according to an embodiment. FIG. 29 is a plan view illustrating an upper surface of a first stacking portion 121 that is included in the semiconductor device illustrated in FIG. 28. FIG. 30 is a plan view illustrating an upper surface of a second stacking portion 122 that is included in the semiconductor device illustrated in FIG. 28. FIG. 28 illustrates a portion corresponding to a left portion in FIG. 1, and FIG. 29 and FIG. 30 illustrate a portion corresponding to a left portion in FIG. 4. FIG. 31 conceptually illustrates separation structures 146 in the first stacking portion 121 and the second stacking portion 122 that are included in the semiconductor device illustrated in FIG. 28.

Referring to FIG. 28 to FIG. 31, in an embodiment, in a plurality of gate stacking portions (e.g., a first stacking portion 121 and a second stacking portion 122) included in a gate stacking structure 120, second separation structures 146b may have different planar shapes.

For example, as illustrated in FIG. 29, in the first stacking portion 121, a second separation structure 146b may have a shape extending in a first direction. For example, as illustrated in FIG. 30, in the second stacking portion 122, a second separation structure 146b may include a plurality of separation portions 1460 that extend in the first direction and are spaced apart from in the first direction. By a difference in planar shape of the second separation structure 146b of the first stacking portion 121 and the second separation structure 146b of the second stacking portion 122, a stress applied to a semiconductor device may be relieve, or the gate stacking structure 120 may be stably supported.

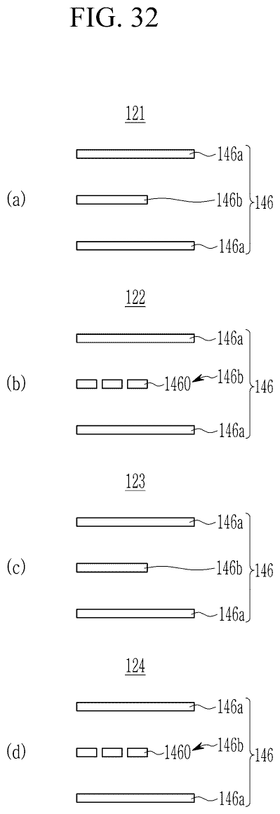

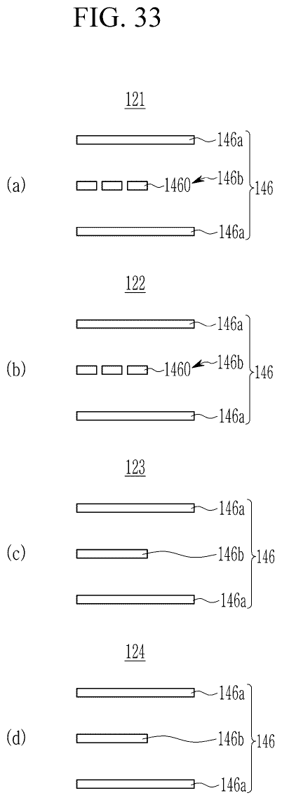

In FIG. 28 to FIG. 31, it is illustrated as an example that the first stacking portion 121 and the second stacking portion 122 are included. However, the gate stacking structure 120 may include three or more stacking portions, and second separation structures 146b in three or more stacking portions may have any of various planar shapes. Referring to FIG. 32 and FIG. 33, an example in which a gate stacking structure 120 includes four stacking portions will be described.

FIG. 32 conceptually illustrates separation structures 146 in a plurality of gate stacking portions that are included in a semiconductor device according to an embodiment. FIG. 33 conceptually illustrates separation structures 146 in a plurality of gate stacking portions that are included in a semiconductor device according to an embodiment.

As illustrated in FIG. 32 and FIG. 33, a gate stacking structure 120 may include a first stacking portion 121, a second stacking portion 122, a third stacking portion 123, and a fourth stacking portion 124.

For example, as illustrated in FIG. 32, a second separation structure 146b in the first stacking portion 121 may have a shape extending in a first direction (an X-axis direction in the drawings), and a second separation structure 146b in the second stacking portion 122 may include a plurality of separation portions 1460 that extend in the first direction and are spaced apart from in the first direction. A second separation structure 146b in the third stacking portion 123 may have a shape extending in the first direction, and a second separation structure 146b in the fourth stacking portion 124 may include a plurality of separation portions 1460 that extend in the first direction and are spaced apart from in the first direction. In some embodiments, a second separation structure 146b in each of the first stacking portion 121 and the third stacking portion 123 may include a plurality of separation portions 1460, and a second separation structure 146b in each of the second stacking portion 122 and the fourth stacking portion 124 may have a shape extending in the first direction. In some embodiments, as illustrated in FIG. 33, a second separation structure 146b in each of the first stacking portion 121 and the second stacking portion 122 may include a plurality of separation portions 1460, and a second separation structure 146b in each of the third stacking portion 123 and the fourth stacking portion 124 may have a shape extending in the first direction. In some embodiments, a second separation structure 146b in each of the first stacking portion 121 and the second stacking portion 122 may have a shape extending in the first direction, and a second separation structure 146b in each of the third stacking portion 123 and the fourth stacking portion 124 may include a plurality of separation portions 1460.

In some embodiments, a second separation structure 146b in at least one of the first to fourth stacking portions 121, 122, 123, and 124 may include a plurality of separation portions 1460, and a second separation structure 146b in the other of the first to fourth stacking portions 121, 122, 123, and 124 may have a shape extending in the first direction (the X-axis direction in the drawings). In some embodiments, a second separation structure 146b in at least one of the first to fourth stacking portions 121, 122, 123, and 124 may have a shape extending in the first direction, and a second separation structure 146b in the other of the first to fourth stacking portions 121, 122, 123, and 124 may include a plurality of separation portions 1460. Other various modified embodiments are possible.

However, the embodiments are not limited to the planar shapes of the second separation structures 146b in the plurality of gate stacking portions illustrated in FIG. 32 and FIG. 33, and the planar shapes of the second separation structure 146b in the plurality of gate stacking portions may be variously modified.

By a difference in planar shape of the second separation structure 146b of the first stacking portion 121 and the second separation structure 146b of the second stacking portion 122, a stress applied to a semiconductor device may be relieve, or the gate stacking structure 120 may be stably supported.

FIG. 34 is a plan view schematically illustrating a portion of a semiconductor device according to an embodiment. FIG. 34 illustrates a portion corresponding to FIG. 4.

Referring to FIG. 34, a plurality of gate contacts 180 that are connected to a plurality of gate electrodes 130 overlapping each other in a plan view may be disposed at different positions in a second direction (a Y-axis direction in the drawings). For example, in a first gate contact 1801, a third gate contact 1803, a fifth gate contact 1805, and a seventh gate contact 1807 disposed in a first row in the second direction, at least one may be disposed at a position different from a position of another one in the second direction. For example, in a second gate contact 1802, a fourth gate contact 1804, a sixth gate contact 1806, and an eighth gate contact 1808 disposed in a second row in the second direction, at least one may be disposed at a position different from a position of another one in the second direction. This may be because an edge position of an upper gate electrode of the plurality of gate electrodes 130 and an edge position of a lower gate electrode of the plurality of gate electrodes 130 are different from each other by a process error or the like.

For example, as illustrated in FIG. 34, a distance between an edge 1307e of a seventh gate electrode disposed in a lower position and a first separation structure 146a adjacent thereto may be greater than an edge 1301e of a first gate electrode disposed in an upper portion and the first separation structure 146a adjacent thereto. The distance may refer to a distance in the second direction (the Y-axis direction in the drawings), for example, a minimum distance. In the second direction (the Y-axis direction in the drawings), the seventh gate contact 1807 may be disposed to be electrically connected to the seventh gate electrode, and the first gate contact 1801 may be disposed to be electrically connected to the first gate electrode. Accordingly, in the second direction, a distance between a center of the seventh gate contact 1807 and the first separation structure 146a adjacent thereto may be greater than a distance between a center of the first gate contact 1801 and the first separation structure 146a adjacent thereto. That is, in the second direction, a position of the seventh gate contact 1807 may be different from a position of the first gate contact 1801.

For a clear understanding, in FIG. 34 and the above description, the first gate contact 1801 and the seventh gate contact 1807 are described as an example, but the embodiments are not limited thereto. In the above description, it is described as an example that an edge position of an upper gate electrode of the plurality of gate electrodes 130 and an edge position of a lower gate electrode of the plurality of gate electrodes 130 are different from each other by a process error, but the embodiments are not limited thereto. An embodiment may be applied to any of various cases in which edge positions of the plurality of gate electrodes 130 are different to each other in the plurality of gate electrodes 130 overlapping each other in a plan view. In some embodiments, even when the edge positions of the plurality of gate electrodes 130 may be same in the plurality of gate electrodes 130 overlapping each other in a plan view, the plurality of gate contacts 180 that are connected to the plurality of gate electrodes 130 may be disposed at different positions in the second direction in a plan view. In this instance, connection parts 180c of the plurality of gate contacts 180 may have different areas such that the plurality of gate contacts 180 are electrically connected to the plurality of gate electrodes 130, respectively.

In some embodiments, in a first direction (an X-axis direction in the drawings), an interval between the plurality of gate contacts 180 may have a first interval and a second interval that are different from each other. For example, in the first gate contact 1801, the third gate contact 1803, the fifth gate contact 1805 and the seventh gate contact 1807 disposed in the first row in the second direction (the Y-axis direction in the drawings), an interval between the plurality of gate contacts 180 may have a first interval and a second interval that are different from each other. For example, in the second gate contact 1802, the fourth gate contact 1804, the sixth gate contact 1806, and the eighth gate contact 1808 disposed in the second row in the second direction, an interval between the plurality of gate contacts 180 may have a first interval and a second interval that are different from each other. The interval between the plurality of gate contacts 180 may refer to an interval between a plurality of first portions included in the plurality of gate contacts 180 in the first direction (the X-axis direction in the drawings).

In FIG. 34, it is illustrated as an example that an interval between the fourth gate contact 1804 and the sixth gate contact 1806 is greater than an interval between the second gate contact 1802 and the fourth gate contact 1804, and an interval between the sixth gate contact 1806 and the eighth gate contact 1808 is greater than the interval between the fourth gate contact 1804 and the sixth gate contact 1806. For example, in a plan view, a connection part 180c of the second gate contact 1802 and a connection part 180c of the fourth gate contact 1804 may overlap each other. In a plan view, the connection part 180c of the fourth gate contact 1804 and a connection part 180c of the sixth gate contact 1806 may not overlap each other, and the connection part 180c of the sixth gate contact 1806 and a connection part 180c of the eighth gate contact 1808 may not overlap each other. However, the embodiments are not limited to the arrangement of the second gate contact 1802, the fourth gate contact 1804, the sixth gate contact 1806, and the eighth gate contact 1808 illustrated in FIG. 34. Therefore, positions, an arrangement, or the like of the plurality of gate contacts 180 may be variously modified.

As described in the above, in an embodiment, positions of the plurality of gate contacts 180 may be variously modified in the first direction and/or the second direction.

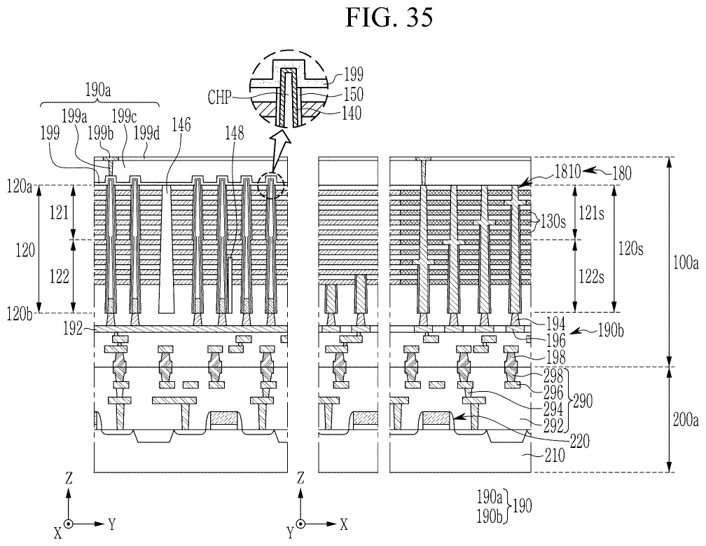

FIG. 35 is a partial cross-sectional view schematically illustrating a semiconductor device 20 according to an embodiment.

Referring to FIG. 35, a semiconductor device according to an embodiment may be a bonding structure bonded by a chip-to-chip (C2C) bonding process, a chip-to-wafer bonding process, or a wafer-to-wafer bonding process. For example, a lower chip including a circuit region 200a where a peripheral circuit structure is disposed on a first substrate 210 may be manufactured, an upper chip including a cell region 100a where a memory cell structure is disposed on a preliminary substrate may be manufactured, and a semiconductor device 20 may be manufactured by bonding the lower chip and the upper chip.

The circuit region 200a may include a first substrate 210, a circuit element 220, and a circuit wiring portion 290. The circuit wiring portion 290 may include an insulation layer 292, a contact via 294, a wiring layer 296, and a bonding structure 298 that is disposed in a surface facing the cell region 100a. A region other than the bonding structure 298 in the surface facing the cell region 100a may be covered by a bonding insulation layer.

The cell region 100a may include a stacking structure that includes a gate stacking structure 120 and an insulation stacking structure 120s, a channel structure CH, a penetration contact 170, and a cell wiring portion 190.

The cell wiring portion 190 may include a first cell wiring portion 190a disposed on a first surface 120a of the stacking structure and a second cell wiring portion 190b disposed on a second surface 120b of the stacking structure. For example, the first cell wiring portion 190a may include a horizontal conductive layer 199, a penetration via 199a, a connection wiring 199b. The penetration via 199a may pass through an insulation layer 199c to be electrically connected to the horizontal conductive layer 199. The connection wiring 199b may be electrically connected to the penetration via 199a. For example, the second cell wiring portion 190b may include a bit line 192, a contact via 194, a connection wiring 196, and a bonding structure 198 that is disposed in a surface facing the circuit region 200a. A region other than the bonding structure 198 in the surface facing the circuit region 200a may be covered by a bonding insulation layer.

For a clear understanding and simple illustration, it is illustrated as an example that the connection wiring 199b of the first cell wiring portion 190a includes a single wiring layer, and an insulation layer 199d may be disposed in a region other the single wiring layer. However, the embodiments are not limited thereto. In some embodiments, the connection wiring 199b of the first cell wiring portion 190a may include a plurality of wiring layers, and may further include a contact via.

In an embodiment, a first contact 1810 of a gate contact 180 may be electrically connected to a first wiring portion (e.g., the first cell wiring portion 190a) on the first surface 120a of the stacking structure (e.g., the insulation stacking structure 120s) through a first portion, and may be electrically connected to a second wiring portion (e.g., the second cell wiring portion 190b) on the second surface 120b of the stacking structure (e.g., the insulation stacking structure 120s) through a second portion. That is, the first contact 1810 may be a first connection contact that is electrically connected to the first wiring portion and the second wiring portion on opposite sides of the stacking structure. In FIG. 35, the first contact 1810 may be a base contact that does not include an expanded portion.

However, the embodiments are not limited thereto, and the first contact 1810 may include at least one of the first connection contact, a second connection contact, the base contact, and an expanded contact, and/or the gate contact 180 may further include a second contact.

In an embodiment, the gate stacking structure 120 may be sequentially stacked on a lower portion of the first cell wiring portion 190a in FIG. 35, and may have a structure in which a gate stacking structure 120 illustrated in FIG. 1 is disposed in a vertically inverted manner. The channel structure CH passing through the gate stacking structure 120 may have a structure in which a channel structure CH illustrated in FIG. 2 is disposed in a vertically inverted manner. Accordingly, in a cross-sectional view, the channel structure CH may have an inclined side surface such that a width of the channel structure CH decreases far away from the circuit region 200a. A channel pad and the bit line 192 at an upper portion of the gate stacking structure 120 may be adjacent to the circuit region 200a.

For example, the bonding structure 298 of the circuit region 200a and/or the bonding structure 198 of the cell region 100a may include aluminum, copper, tungsten, or an alloy including the same. For example, the bonding structure 298 of the circuit region 200a and the bonding structure 198 of the cell region 100a may include copper such that the cell region 100a and the circuit region 200a may be bonded (e.g., directly bonded) to each other by copper-to-copper bonding.

In an embodiment, the channel structure CH may include a protruding portion CHP protruding from the first surface 120a of the gate stacking structure 120. A gate dielectric layer 150 is not disposed in the protruding portion CHP and a channel layer 140 disposed in the protruding portion CHP may be exposed to an outside. The horizontal conductive layer 199 may be electrically connected to the channel layer 140 in the protrusion portion CHP. However, the embodiments are not limited thereto, and horizontal conductive layers 112 and 114 may be included as illustrated in FIG. 1. Other various modified embodiments are possible.

In an embodiment, the semiconductor device may include an input/output pad and an input/output connection wiring electrically connect to the input/output pad. The input/output connection wiring may be electrically connected to a part of bonding structures 198 of the cell region 100a. The input/output pad may be disposed, for example, on the insulation layer 199d. In some embodiments, an additional input/output pad electrically connected to the circuit region 200a may be provided.

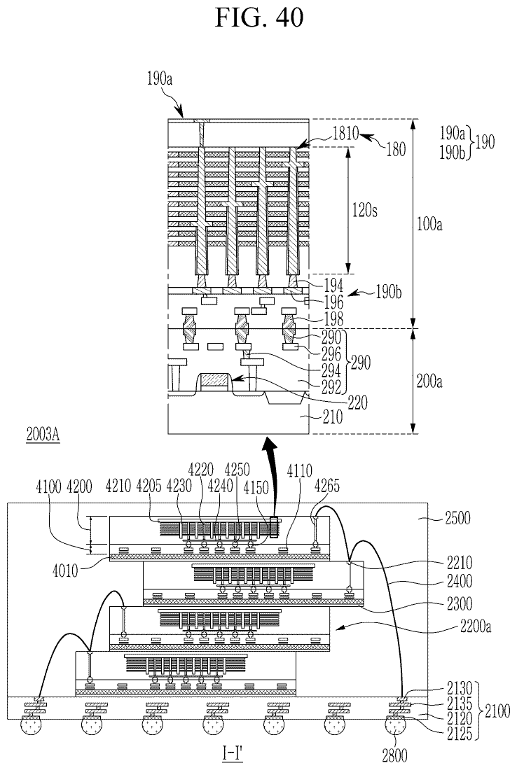

For example, the circuit region 200a and the cell region 100a may be portions corresponding to a first structure 1100F and a second structure 1100S of a semiconductor device 1100 included in an electronic system 1000 illustrated in FIG. 37, respectively. For example, the circuit region 200a and the cell region 100a may be regions including a first structure 4100 and a second structure 4200 of a semiconductor chip 2200a illustrated in FIG. 40, respectively.

In the above description and the drawings, it is described and illustrated as an example that, when the insulation stacking structure 120s includes a plurality of insulation stacking portions corresponding to a plurality of gate stacking portions, the plurality of insulation stacking portions are formed, and a plurality of through holes in which a plurality of gate contacts 180 are disposed, respectively, are formed. For example, when the insulation stacking structure 120s includes first and second insulation stacking portions 121s and 122s, the first and second insulation stacking portions 121s and 122s may be formed, and the plurality of through holes in which the plurality of gate contacts 180 are disposed, respectively, may be formed. However, the embodiments are not limited thereto.

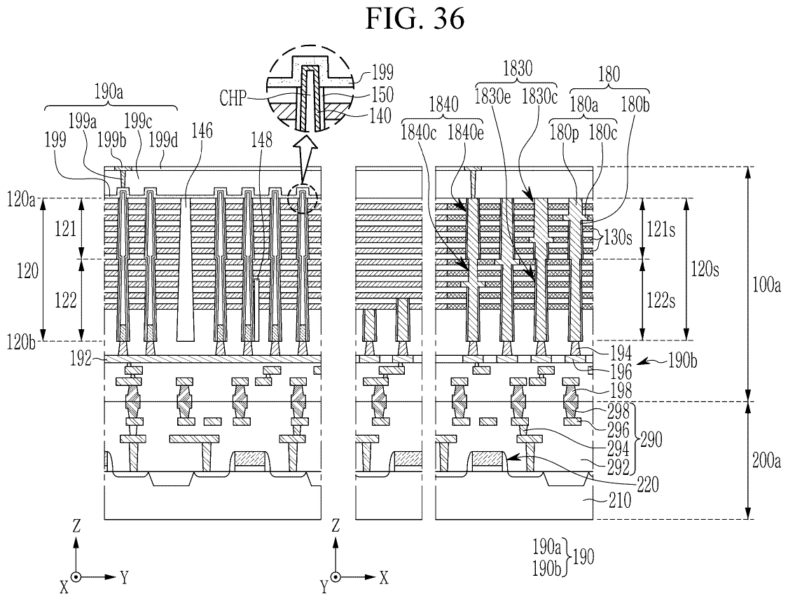

In some embodiments, as illustrated in FIG. 36, when an insulation stacking structure 120s include a plurality of insulation stacking portions, a partial process may be repeatedly performed. In the partial process, a portion corresponding to at least one of the plurality of insulation stacking portions may be formed, and thereafter, a process of forming portions of a plurality of through holes may be formed.

For example, when the insulation stacking structure 120s includes first and second insulation stacking portions 121s and 122s, the first insulation stacking portion 121s may be formed and portions of the plurality of through holes may be formed, and thereafter, the second insulation stacking portion 122s may be formed and other portions of the plurality of through holes may be formed.

For example, after the first insulation stacking portion 121s may be formed, a portion (e.g., a first connection portion 1830c) of a through hole in which a first connection gate contact 1830 is disposed and a portion (e.g., a second extension portion 1840e) of a through hole in which a second connection gate contact 1840 is disposed. The first connection gate contact 1830 may be a gate contact 180 including a connection part 180c in the first insulation stacking portion 121s, and the second connection gate contact 1840 may be a gate contact 180 including a connection part 180c in the second insulation stacking portion 122s. The first connection portion 1830c may include a first through portion, a side insulation layer 180b, a connection through portion, and a second through portion. The second extension portion 1840e may pass through the entirety of the first insulation stacking portion 121s.

The first through portion of the first connection portion 1830c may be formed by a first etching process as illustrated in FIG. 7 to FIG. 10. The side insulation layer of the first connection portion 1830c may be formed by a process as illustrated in FIG. 11 to FIG. 13. The connection through portion of the first connection portion 1830c may be formed by a process as illustrated in FIG. 14. The second through portion of the first connection portion 1830c may be formed by a second etching process as illustrated in FIG. 15. A through portion of the second extension portion 1840e may be formed by the first etching process as illustrated in FIG. 7 to FIG. 10. The side insulation layer 180b may be formed on a side surface of the through portion of the second extension portion 1840e by the process as illustrated in FIG. 11 to FIG. 13. However, the embodiments are not limited thereto, and the side insulation layer 180b may not be formed on a side surface of the through portion of the second extension portion 1840e. A penetration sacrificial layer may be formed in the first connection portion 1830c and the second extension portion 1840e.

Subsequently, the second insulation stacking portion 122s may be formed. A portion (e.g., a second connection portion 1840c) of the through hole in which the second connection gate contact 1840 is disposed and a portion (e.g., a first extension portion 1830e) of the through hole in which the first connection gate contact 1830 is disposed may be formed. The second connection portion 1840c may include a first through portion, a side insulation layer 180b, a connection through portion, and a second through portion. The first extension portion 1830e may pass through the entirety of the second insulation stacking portion 122s.

The first through portion of the second connection portion 1840c may be formed by a first etching process as illustrated in FIG. 7 to FIG. 10. The side insulation layer of the second connection portion 1840c may be formed by a process as illustrated in FIG. 11 to FIG. 13. The connection through portion of the second connection portion 1840c may be formed by a process as illustrated in FIG. 14. The second through portion of the second connection portion 1840c may be formed by a second etching process as illustrated in FIG. 15. The through portion of the first extension portion 1830e may be formed by the first etching process as illustrated in FIG. 7 to FIG. 10. The side insulation layer 180b may be formed on a side surface of the through portion of the first extension portion 1830e by the process as illustrated in FIG. 11 to FIG. 13. However, the embodiments are not limited thereto, and the side insulation layer 180b may not be formed on the side surface of the through portion of the first extension portion 1830e. The penetration sacrificial layer may be removed in the first connection portion 1830c and the second extension portion 1840e to form through holes.

The first connection gate contact 1830 may have a bent portion due to a difference in width at a boundary between the first insulation stacking portion 121s and the second insulation stacking portion 122s. For example, the first connection gate contact 1830 may have the bent portion due to a difference in width between the first connection portion 1830c and the first extension portion 1830e at the boundary between the first insulation stacking portion 121s and the second insulation stacking portion 122s. The second connection gate contact 1840 may have a bent portion due to a difference in width at the boundary between the first insulation stacking portion 121s and the second insulation stacking portion 122s. For example, the second connection gate contact 1840 may have the bent portion due to a difference in width between the second extension portion 1840e and the second connection portion 1840c at the boundary between the first insulation stacking portion 121s and the second insulation stacking portions 122s. However, the embodiments are not limited thereto.

Subsequently, a conductive portion 180a may be formed by filling a conductive material in the through hole. Thereby, the gate contact 180 may be formed. Thereby, it may be suitable to an embodiment in which a number of gate electrodes included in the gate stacking structure 120 is large, and a process of forming the gate contact 180 may be easily performed.

A process of forming the opening for a separation structure, a process of replacing a sacrificial insulation layer 130s with a gate electrode, a process of forming a separation structure 146 may be performed after a process of forming second insulation stacking portion 122s and a process of forming a portion of the through hole in the second insulation stacking portion 122s. In some embodiments, the process of forming the opening for the separation structure, the process of replacing the sacrificial insulation layer 130s with the gate electrode, the process of forming the separation structure 146 may be performed between the process of forming the second insulation stacking portion 122s and the process of forming the portion of the through hole in the second insulation stacking portion 122s.

In the above description with reference to FIG. 36, it is described as an example that the insulation stacking structure 120s includes the first and second insulation stacking portions 121s and 122s. However, the embodiments are not limited thereto. In some embodiments, the insulation stacking structure 120s may include three or more insulation stacking portions. In this instance, a partial process may be repeatedly performed. In the partial process, a portion (e.g., one or a plurality of insulation stacking portions) of the plurality of insulation stacking portions may be formed and a portion of the through hole may be formed.

In FIG. 36, it is illustrated as an example that a semiconductor device is a bonding semiconductor device. However, the embodiments are not limited thereto. In some embodiments, an insulation stacking structure 120s may include a plurality of insulation stacking portions in a semiconductor device illustrated in FIG. 1. In this instance, a partial process may be repeatedly performed. In the partial process, a portion corresponding to at least one of the plurality of insulation stacking portions may be formed, and thereafter, portions of the plurality of through holes may be formed in the at least one of the plurality of insulation stacking portions.

An example of an electronic system including a semiconductor device will be described in detail below.

FIG. 37 is a view schematically illustrating an electronic system including a semiconductor device according to an embodiment.

Referring to FIG. 37, an electronic system 1000 according to an embodiment may include a semiconductor device 1100 and a controller 1200 that is electrically connected to the semiconductor device 1100. The electronic system 1000 may be a storage device that includes one or a plurality of semiconductor devices 1100 or an electronic device that includes the storage device. For example, the electronic system 1000 may be a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIG. 1 to FIG. 36. The semiconductor device 1100 may include a first structure 1100F and a second structure 1100S that is disposed on the first structure 1100F. In some embodiments, the first structure 1100F may be disposed next to the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 that are adjacent to the common source line CSL, upper transistors UT1 and UT2 that are adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to an embodiment.

In an embodiment, the lower transistor LT1 or LT2 may include a ground selection transistor, and the upper transistor UT1 or UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

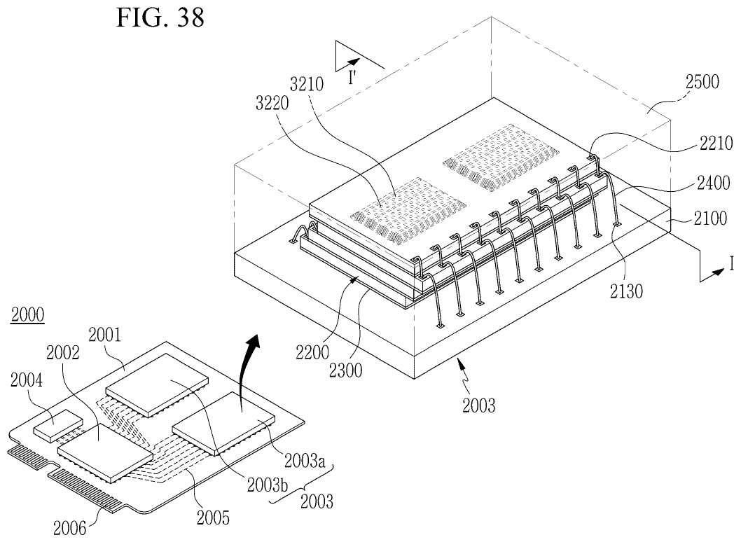

FIG. 38 is a perspective view schematically illustrating an electronic system including a semiconductor device according to an embodiment.

Referring to FIG. 38, an electronic system 2000 according to an embodiment may include a main substrate 2001, a controller 2002 that is mounted on the main substrate 2001, one or more semiconductor packages 2003, and a DRAM 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and an arrangement of the plurality of pins in the connector 2006 may vary depending on a communication interface between the electronic system 2000 and the external host. In an embodiment, the electronic system 2000 may communicate with the external host according to any one of interfaces such as a universal serial bus (USB), a peripheral component interconnect express (PCI-Express), a serial advanced technology attachment (SATA), or an M-Phy for a universal flash storage (UFS). In an embodiment, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from each other. Each of the first and second semiconductor packages 2003a and 2003b may be a semiconductor package that includes a plurality of semiconductor chips 2200. Each of the first and second semiconductor packages 2003a and 2003b may include a package substrate 2100, a semiconductor chip 2200 that is disposed on the package substrate 2100, an adhesive layer 2300 at a lower surface of each semiconductor chip 2200, a connection structure 2400 that electrically connects the semiconductor chip 2200 and the package substrate 2100, and a molding layer 2500 that covers the semiconductor chip 2200 and the connection structure 2400 on the package substrate 2100.

The package substrate 2100 may be a printed circuit board that includes a package upper pad 2130. Each semiconductor chip 2200 may include an input/output pad 2210. The input/output pad 2210 may correspond to an input/output pad 1101 of FIG. 37. Each semiconductor chip 2200 may include a gate stacking structure 3210 and a channel structure 3220. The semiconductor chip 2200 may include a semiconductor device described with reference to FIG. 1 to FIG. 36.

In an embodiment, the connection structure 2400 may be a bonding wire that electrically connects the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to the package upper pad 2130 of the package substrate 2100 using a bonding wire type. According to an embodiment, in each of the first and second semiconductor packages 2003a and 2003b, the semiconductor chips 2200 may be electrically connected to each other by a connection structure that includes a through silicon via (TSV) instead of the connection structure 2400 of the bonding wire type.

In an embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring of the interposer substrate.

FIG. 39 and FIG. 40 are cross-sectional views schematically illustrating semiconductor packages according to embodiments, respectively. FIG. 39 and FIG. 40 respectively illustrate embodiments of the semiconductor package 2003 of FIG. 38, and conceptually illustrate a region obtained by cutting the semiconductor package 2003 of FIG. 38 along a line I-I′.

Referring to FIG. 39, in a semiconductor package 2003, the package substrate 2100 may be a printed circuit board. The package substrate 2100 may include a package substrate body portion 2120, a package upper pad 2130 at an upper surface of the package substrate body portion 2120, a package lower pad 2125 disposed at a lower surface of the package substrate body portion 2120 or exposed through the lower surface of the package substrate body portion 2120, and an internal wiring 2135 electrically connecting the package upper pad 2130 and the package lower pad 2125 inside the package substrate body portion 2120. The package upper pad 2130 may be electrically connected to the connection structure 2400. The package lower pad 2125 may be connected to a wiring pattern 2005 of the main substrate 2001 of the electronic system 2000, as illustrated in FIG. 38, through a conductive connection portion 2800.

The semiconductor chip 2200 may include a semiconductor substrate 3010, and a first structure 3100 and a second structure 3200 sequentially stacked on the semiconductor substrate 3010. The first structure 3100 may include a peripheral circuit region including a peripheral wiring 3110. The second structure 3200 may include a common source line 3205, a gate stacking structure 3210 on the common source line 3205, a channel structure 3220 and a separation structure 3230 passing through the gate stacking structure 3210, a bit line 3240 electrically connected to the channel structure 3220, and a gate connection wiring electrically connected to a word line WL (refer to FIG. 37) of the gate stacking structure 3210.

In a semiconductor chip 2200 or a semiconductor device according to an embodiment, a gate contact 180 may be disposed in an insulation stacking structure to be disposed in a space separated from a penetration dummy structure, and a first through portion of a through hole may be stably formed. Thereby, performance and productivity of the semiconductor chip 2200 or the semiconductor device may be improved.

Each of the semiconductor chips 2200 may include a through wiring 3245 that is electrically connected to the peripheral wiring 3110 of the first structure 3100 and extends into the second structure 3200. The through wiring 3245 may penetrate the gate stacking structure 3210, and may be further provided at an outside of the gate stacking structure 3210. Each semiconductor chip 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In an embodiment, in the semiconductor package 2003, a plurality of semiconductor chips 2200 may be electrically connected to each other by a connection structure 2400 having a bonding wire type. In some embodiments, the plurality of semiconductor chips 2200 or a plurality of portions constituting the plurality of semiconductor chips 2200 may be electrically connected by a connection structure including a through silicon via (TSV).

Referring to FIG. 40, in a semiconductor package 2003A, each semiconductor chip 2200a may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region including a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second bonding structure 4250 electrically connected to the channel structure 4220 and a word line WL (refer to FIG. 37) of the gate stacking structure 4210. For example, the second bonding structure 4250 may be electrically connected to the channel structure 4220 and the word line WL through a bit line 4240 electrically connected to the channel structure 4220 and a gate connection wiring electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In a semiconductor chip 2200a or a semiconductor device according to an embodiment, a gate contact 180 may be disposed in an insulation stacking structure 120s to be disposed in a space separated from a penetration dummy structure, and a first through portion of a through hole may be stably formed. Thereby, performance and productivity of the semiconductor chip 2200a or the semiconductor device may be improved.

Each of the semiconductor chips 2200a may further include an input/output pad 2210 and an input/output connection wiring 4265 at a lower portion of the input/output pad 2210. The input/output connection wiring 4265 may be electrically connected to a part of the second bonding structure 4250.

In an embodiment, in the semiconductor package 2003A, a plurality of semiconductor chips 2200a may be electrically connected to each other by the connection structure 2400 having a bonding wire type. In some embodiments, the plurality of semiconductor chips 2200a or a plurality of portions constituting the plurality of semiconductor chips 2200a may be electrically connected by a connection structure including a through silicon via (TSV).

While some examples have been described in connection with what is presently considered to be some example embodiments, it is to be understood that the disclosure is not limited to the disclosed embodiments, and that the disclosure is intended to cover various modifications and equivalent arrangements included within the spirit and scope of the appended claims.

What is claimed is:

1. A semiconductor device, comprising:
a cell array region, and a connection region including a first region and a second region,
wherein the semiconductor device comprises:
a stacking structure including a gate stacking structure and an insulation stacking structure, wherein the gate stacking structure is in the cell array region and the first region, and includes a plurality of gate electrodes and a plurality of interlayer insulation layers, wherein the insulation stacking structure is in the second region, and includes a plurality of sacrificial insulation layers and the plurality of interlayer insulation layers;
a channel structure passing through the gate stacking structure in the cell array region; and
a plurality of gate contacts in the second region and electrically connected to at least a part of the plurality of gate electrodes in the first region, respectively,
wherein each of the plurality of gate contacts includes a conductive portion and a side insulation layer,
wherein the conductive portion includes a penetration part passing through the insulation stacking structure and a connection part extending horizontally to have an area greater than an area of the penetration part,
wherein the side insulation layer is on at least a portion of a side surface of the conductive portion,
wherein the plurality of gate contacts includes a first contact,
wherein the connection part has a first surface and a second surface opposite to each other, and
wherein the penetration part of the first contact includes a first portion on the first surface of the connection part and a second portion on the second surface of the connection part.

2. The semiconductor device of claim 1, wherein a side surface of the connection part in the second region is connected to a side surface of one of the plurality of gate electrodes in the first region.

3. The semiconductor device of claim 1, wherein the side insulation layer of the first contact is on a side surface of the first portion and is spaced apart from the second portion.

4. The semiconductor device of claim 1, further comprising:
a penetration dummy structure in the first region and separated from the plurality of gate contacts in the second region.

5. The semiconductor device of claim 1, further comprising:
a first wiring portion on a first surface of the stacking structure; and
a second wiring portion on a second surface of the stacking structure opposite to the first surface of the stacking structure,
wherein the first contact includes a first connection contact, and
wherein, in the first connection contact, the first portion is electrically connected to the first wiring portion, and the second portion is electrically connected to the second wiring portion.

6. The semiconductor device of claim 1, further comprising:
a first wiring portion on a first surface of the stacking structure; and
a second wiring portion on a second surface of the stacking structure opposite to the first surface of the stacking structure,
wherein the first contact includes a second connection contact, and
wherein, in the second connection contact, the first portion is electrically connected to one of the first wiring portion and the second wiring portion, and is electrically insulated from the other of the first wiring portion and the second wiring portion.

7. The semiconductor device of claim 1,
wherein the plurality of gate contacts includes a second contact having a structure or a shape different from a structure or a shape of the first contact, and
wherein, in the second contact, the connection part is in an end portion of the penetration part.

8. The semiconductor device of claim 1,
wherein the first contact includes an expanded portion, and
wherein the expanded portion extends horizontally from the second portion, and is electrically insulated from the plurality of gate electrodes of the gate stacking structure.

9. The semiconductor device of claim 8, wherein an area of the expanded portion is less than the area of the connection part.

10. The semiconductor device of claim 8, wherein the expanded portion is in an end portion of the first contact.

11. The semiconductor device of claim 8, wherein the second portion passes through the expanded portion, and includes a portion on a first surface of the expanded portion and a portion on a second surface of the expanded portion.

12. The semiconductor device of claim 8,
wherein the expanded portion includes a plurality of expanded portions, and
wherein the plurality of expanded portions has a same area or has different areas.

13. The semiconductor device of claim 1, further comprising:
an expanded dummy structure including a dummy penetration part and a dummy expanded portion,
wherein the dummy penetration part passes through the insulation stacking structure, and the dummy expanded portion extends horizontally to have an area greater than an area of the dummy penetration part.

14. The semiconductor device of claim 13, wherein the expanded dummy structure includes at least one of an insulating material and a conductive material.

15. The semiconductor device of claim 1, further comprising:
a separation structure passing through the stacking structure,
wherein the separation structure includes a plurality of first separation structures and a second separation structure,
wherein each of the plurality of first separation structures extends in a first direction,
wherein the second separation structure is between two adjacent first separation structures of the plurality of first separation structures and extends to have a length less than a length of the plurality of first separation structures, and
wherein the second region is between the two adjacent first separation structures and is spaced apart from the second separation structure.

16. The semiconductor device of claim 15, wherein the second separation structure includes a plurality of separation portions spaced apart from each other in the first direction.

17. The semiconductor device of claim 15,
wherein the gate stacking structure includes a first stacking portion and a second stacking portion stacked on the first stacking portion in a thickness direction, and
wherein the second separation structure in the first stacking portion and the second separation structure in the second stacking portion have different planar shapes.

18. The semiconductor device of claim 1,
wherein the plurality of gate electrodes includes a string selection electrode, and
wherein, in the first region, a string selection contact is electrically connected to the string selection electrode and has a shape different from a shape of the plurality of gate electrodes.

19. A semiconductor device, comprising:
a stacking structure including a gate stacking structure, wherein the gate stacking structure includes a plurality of gate electrodes and a plurality of interlayer insulation layers;
a channel structure passing through the gate stacking structure; and
a plurality of gate contacts passing through the stacking structure and electrically connected to at least a part of the plurality of gate electrodes, respectively,
wherein each of the plurality of gate contacts includes a conductive portion and a side insulation layer,
wherein the conductive portion includes a penetration part passing through the stacking structure and a connection part extending horizontally to have an area greater than an area of the penetration part,
wherein the side insulation layer is on a side surface of the conductive portion,
wherein the plurality of gate contacts includes a first contact,
wherein the connection part has a first surface and a second surface opposite to each other,
wherein the penetration part of the first contact includes a first portion on the first surface of the connection part and a second portion on the second surface of the connection part, and
wherein the side insulation layer of the first contact is on a side surface of the first portion and is spaced apart from the second portion.

20. An electronic system, comprising:
a main substrate;
a semiconductor device on the main substrate; and
a controller electrically connected to the semiconductor device on the main substrate,
wherein the semiconductor device includes a cell array region, and a connection region including a first region and a second region,
wherein the semiconductor device comprises:
a stacking structure including a gate stacking structure and an insulation stacking structure, wherein the gate stacking structure is in the cell array region and the first region, and includes a plurality of gate electrodes and a plurality of interlayer insulation layers, wherein the insulation stacking structure is in the second region, and includes a plurality of sacrificial insulation layers and the plurality of interlayer insulation layers;
a channel structure passing through the gate stacking structure in the cell array region; and
a plurality of gate contacts in the second region and electrically connected to at least a part of the plurality of gate electrodes in the first region, respectively,
wherein each of the plurality of gate contacts includes a conductive portion and a side insulation layer,
wherein the conductive portion includes a penetration part passing through the insulation stacking structure and a connection part extending horizontally to have an area greater than an area of the penetration part,
wherein the side insulation layer is on at least a portion of a side surface of the conductive portion,
wherein the plurality of gate contacts includes a first contact,
wherein the connection part has a first surface and a second surface opposite to each other, and
wherein the penetration part of the first contact includes a first portion on the first surface of the connection part and a second portion on the second surface of the connection part.
